(19) United States
(12) Patent Application Publication
(10) Pub. No.: US 2013/0009300 A1
(43) Pub. Date: Jan. 10, 2013

(54) SEMICONDUCTOR DEVICE AND METHOD FOR MANUFACTURING SAME

(75) Inventors: Yuichi Yato, Kanagawa (JP); Hiroi Oka, Kanagawa (JP)

(73) Assignee: RENESAS ELECTRONICS CORPORATION, Kawasaki-shi, Kanagawa (JP)

(21) Appl. No.: 13/635,455

(22) PCT Filed: Mar. 31, 2010
(86) PCT No.: PCT/JP2010/055847

§ 371 Date: Sep. 17, 2012

(51) Int. Cl. H01L 23/495; H01L 21/60

(52) U.S. Cl. 257/676; 438/123; 257/E21.506; 257/E23.031

(57) ABSTRACT

A dug portion (50) in which a die-bonding material is filled is provided to a lower surface of a stamping nozzle (42) used in a step of applying the die-bonding material onto a chip mounting portion of a wiring board. Planar dimensions of the dug portion (50) are smaller than external dimensions of a chip to be mounted on the chip mounting portion. In addition, a depth of the dug portion (50) is smaller than a thickness of the chip. When the thickness of the chip is 100 μm or smaller, a problem of crawling up of the die-bonding material to an upper surface of the chip is avoided by applying the die-bonding material onto the chip mounting portion using the stamping nozzle (42).

### TECHNICAL FIELD

The present invention relates to a semiconductor device and a method of manufacturing the same and more particularly relates to technique effectively applied to a semiconductor device in which a semiconductor chip is mounted on a wiring board using a paste-like die-bond material and a method of manufacturing the semiconductor device.

### BACKGROUND ART

Patent Document 1 (Japanese Patent Application Laid-Open Publication No. 2007-149784) discloses a solder supplying apparatus having a nozzle at a lower portion of a crucible of a sealed container structure and discharges a liquid solder for die-bonding accommodated on the crucible on a stamping basis. The crucible includes solder heating means for heating a solid solder to be a liquid solder, discharge control means which controls switching of positive pressure and negative pressure of the inner pressure of the crucible, a fluid level sensor which detects volume of the liquid solder, and solder replenish means which replenishes a solid solder into the crucible based on detected signals of the fluid level sensor.

Patent Document 2 (Japanese Patent Application Laid-Open Publication No. 2004-281646) discloses a method and device of adhering a chip element to a circuit board using an adhesive such as solder. The adhesion apparatus includes a feeding mechanism which feeds the adhesive to the circuit board at a high temperature by a predetermined amount, a box clamp jig having a concave portion for shaping the adhesive being melted in a predetermined size and a predetermined thickness, an arrangement mechanism which arranges chip elements on the shaped adhesive, and moving means which moves the circuit board at a predetermined pitch. The adhesive being melted on the circuit board at a high temperature is shaped into a rectangular shape by the box clamp jig and then the chip elements are arranged on the shaped melted adhesive to adhere the chip elements on the circuit board thereafter as the melted adhesive is solidified.

Patent Document 3 (Japanese Patent Application Laid-Open Publication No. 2002-273567) discloses a spanker tool which makes up the shape of an adhesive such as solder dropped on a work such as a lead frame into a predetermined shape. This spanker tool includes a concave portion for making up the adhesive into a predetermined shape and grooves for forming protruding portions in a plurality of lines or dots on a surface of the adhesive are provided to a bottom surface of the concave portion. When a semiconductor chip is arranged on the adhesive to which the protruding portions, the semiconductor chip is supported by line contact or point contact by the protruding portions of the adhesive at a plurality of parts, so that erroneous mounting of the semiconductor chip being tilted to the work is prevented.

Patent Document 4 (Japanese Patent Application Laid-Open Publication No. 2000-232114) discloses a die-bonding method and an apparatus for adhering a semiconductor chip on a lead frame by solder. When a position of a lead frame is determined at a solder applying portion of the die-bonding apparatus, a melted solder is supplied onto the lead frame. Next, when the lead frame is fed to a solder spreading portion, the melted solder on the lead frame is spread by a spreading tool and also shaped into a rectangular shape. Next, when the lead frame is fed to an adhering portion, the semiconductor chip is pressed onto the spread solder.

However, above-described Patent Documents do not describe technique of solving a problem upon mounting a thinned semiconductor chip on a lead frame or wiring board, that is, crawling up of a part of a die-bonding material that leaked to the outside from a lower surface to an upper surface of the semiconductor chip.

Moreover, according to all of above-described Patent Documents, a semiconductor chip is mounted on a melted solder. A side surface of the semiconductor chip is formed of Si (silicon) and silicon cannot be wet on a melted solder (i.e., metallic bonding is not formed; silicon rejects the melted solder) and so the phenomenon of crawling up of solder from the side surface to the upper surface does not occur in the first place. Above-described Patent Documents yet do not notice a phenomenon of crawling up (riding) of die-bonding material onto an upper surface of a chip upon mounting the thinned chip on a paste-like die-bonding material such as Ag paste, insulating paste and solder paste.

### PRIOR ART DOCUMENTS

### Patent Documents

Patent Document 1: Japanese Patent Application Laid-Open Publication No. 2007-149784

Patent Document 2: Japanese Patent Application Laid-Open Publication No. 2004-281646

Patent Document 3: Japanese Patent Application Laid-Open Publication No. 2002-273567

Patent Document 4: Japanese Patent Application Laid-Open Publication No. 2000-232114

### DISCLOSURE OF THE INVENTION

### Problems to be Solved by the Invention

Along with down-sizing and thinning of electronic devices and mobile devices, down-sizing and thinning of semiconductor packages to be mounted on these devices have been desired.

To achieve down-sizing and thinning of a semiconductor package, for example, in the case of BGA (Ball Grid Array) etc. of a wire bonding structure, an effective countermeasure is down-sizing semiconductor chips (hereinafter, simply called chip) embedded inside the semiconductor package and arranging a bonding lead of a surface of a wiring board electrically connected to the chip near to the chip.

However, in an actual die-bonding step, upon mounting a chip on a wiring board using a die-bonding material (Ag paste, solder paste, insulating paste etc.), the die-bonding material applied onto the wiring board often leaks to the outside. In that case, when the leaked die-bonding material attaches to an adjacent bonding lead, a wire cannot be connected to the bonding lead.

As a countermeasure of that, upon designing the wiring board, an interval between the chip and the bonding lead is previously widened in consideration of the above-described leakage of the die-bonding material and/or a dam formed of solder resist is provided between the chip and the bonding lead, making the area of the wiring board larger and preventing down-sizing of the semiconductor package.

On the other hand, thinning of a chip embedded in a semiconductor package is effective in suppression of the thickness (mount height) of the whole of the semiconductor package. Also, thinning of a chip, to which power transistors such as power MOSFETs (Metal Oxide Semiconductor Field Effect Transistor) operated at large power of several W (watts) are formed, is effective in not also thinning of the semiconductor package but also reduction of ON resistance of the transistor. This is because the thinner the chip, the shorter current path inside the chip since a back surface of the chip is a drain electrode in the case of power MOSFET.

However, when a chip is thinned, upon mounting the chip on an upper surface of a wiring board (herein after, members to which chips are mounted such as a lead frame, printed wiring board, and ceramic wiring board will be collectively referred to “wiring board”) using a die-bonding material, not only the leakage of die-bonding material mentioned above but also crawling up of a part of the leaked die-bonding material onto an upper surface of the thin chip occur.

For example, when applying a die-bonding material onto a wiring board using a plurality of nozzles (multi-point nozzle), the die-bonding material has a viscosity to some extent not to drop from a tip of the nozzle. Thus, the die-bonding material discharged onto the wiring board from the tip of each of the nozzles is slightly in a mound and there is a spacing corresponding to each interval of the nozzles among the die-bonding materials to each other.

Here, it is necessary to fill the spacing of the die-bonding materials to each other and makes the die-bonding material wet and spread to some extent that leakage of the die-bonding material to the outside of the chip can be confirmed. This is because, when a space (void) not filled with the die-bonding material occurs between the wiring board and the back surface of the mounted chip, even when ultrasonic vibration is applied in the following wire bonding step to join a metal ball (initial ball) formed at a capillary tip with an electrode pad of a chip surface, the ultrasonic vibration is not certainly transmitted due to the void and it is necessary to prevent exfoliation of the metal ball from the electrode pad and exfoliation of the chip from the wiring board (chip exfoliation) occurring by a power caused as the air inside the void is brought into volume expansion by heat applied in a step of solder mounting (solder reflow step) of the finished semiconductor package to a mounting board.

To make the die-bonding material wet and spread to the whole of the back surface of the chip, load is often applied from above upon mounting the chip onto the wiring board to which the die-bonding material is applied. However, when the chip is thinned, a part of the die-bonding material leaked to the outside of the chip becomes prone to crawl up to the upper surface of the chip during application of the load.

FIG. 58 is a graph illustrating a relationship of the frequency of crawling up to the upper surface of the chip of the die-bonding material applied onto the wiring board using the multi-point nozzle and the chip thickness. Here, a lead frame was used as the wiring board and an Ag paste was used as the die-bonding material. From this graph, it is understood that crawling up of the die-bonding material significantly occurs when the thickness of the chip is 100 μm or smaller.

A plurality of electrode pads (bonding pads) formed of a conductive material such as Al (aluminum) are exposed from a surface protective film at an upper surface of a chip to which elements such as MOSFETs are formed. In addition, a plurality of metal wirings for connecting elements to each other or elements and electrode pads are formed in a lower layer of the surface protective film. Occurrence of a problem as explained below has thus revealed when the die-bonding material crawled up to the upper surface of the chip attaches the surface of the electrode pad or the surface of the surface protective film covering the metal wirings.

For example, when the die-bonding material thickly rises to the surface of the electrode pad, connection of a bonding wire onto the electrode pad is impossible in a following wire bonding step. Also, when the die-bonding material thinly attaches to the surface of the electrode pad, the die-bonding material prevents metal bonding between the bonding wire (initial ball) and the electrode pad, posing a failure of pressure bonding or a lack of connection strength to occur.

Further, when the die-bonding material is formed of conductive materials such as an Ag paste or a solder paste, electrical short-circuiting of adjacent electrode pads is caused to occur via the die-bonding material. Particularly, the study by the inventors of the present invention has also revealed a possibility that, when the die-bonding material formed of an Ag paste attached on the surface protective film, an Ag filler in the Ag paste cuts through the surface protective film (for example, a polyimide resin film having a thickness of about 2 μm) due to thermal stress generated in a baking step of curing the Ag paste and a molding step of resin-sealing the chip, resulting in a short-circuiting between the Ag filer and the metal wiring in the lower layer of the surface protective film.

FIG. 59 schematically illustrates a situation of short-circuiting of the Ag filler in the Ag paste to the metal wiring as the Ag filler cuts through the surface protective film. Here, an example of mounting a chip 1 onto a leadframe LF made of a metal interposing an Ag paste 7 will be described.

A metal wiring 36 formed of a conductive material is formed to an upper most layer of the chip 1 and a surface protective film 19 for protecting the metal wiring 36 is formed to an upper portion of the metal wiring 36. The surface protective film 19 is formed of a polyimide resin film having a thickness of about 2 μm. Meanwhile, the Ag paste 7 is a conductive die-bonding material in which an Ag filler 11 of about 2 to 15 μm diameter in a base material of an epoxy resin or the like are diffused.

Here, when the Ag paste 7 crawled up to the upper surface of the chip 1 attaches to the surface protective film 19 covering the metal wiring 36, the Ag filler 11 among the Ag filler 11 contained in the Ag paste 7 having a larger diameter than the thickness of the surface protective film 19 cuts through the surface protective film 19 and contacts the metal wiring 36 when thermal stress is applied to the Ag paste 7 in a following thermal process (a baking step of curing the Ag paste 7, molding step of resin-sealing the chip 1, etc.). As a result, the metal wiring 36 and the lead frame LF are short-circuited via the Ag paste 7.

Also, when a power MOSFET is formed to the chip 1, a gate electrode pad connected to a gate electrode of the power MOSFET and a source electrode pad connected to a source are formed to the upper surface of the chip 1. Further, a drain electrode is formed to the back surface of the chip 1. Thus, when the Ag paste 7 crawls up to the upper surface of the chip 1, short-circuiting may occur between the drain electrode on the back surface of the chip 1 and the gate electrode pad or the source electrode pad on a main surface of the chip 1 via the Ag paste 7.

In addition, when the die-bonding material crawls up to the upper surface of the chip, a leakage failure may occur upon high-temperature/high-humidity bias test such as PCT (Pressure Cooker Test) or HAST (Highly Accelerated Stress Test) performed after completion of the semiconductor package. For example, the Ag paste or the base material of the insulating paste are often mainly formed of an epoxy-based resin and when the resin exists near the electrode pads, ion components (Na⁺, Cl⁻ etc.) in the paste move during the bias test and makes a leakage failure in μA order occur more easily.

Further, the die-bonding material may attach to a lower surface of a collet (bonding nozzle) which sucks and holds the chip upon die-bonding and causes contamination of the upper surfaces of other chips to be sucked and held next. As a countermeasure for preventing the attachment of the die-bonding material to the lower surface of the collet, there is a method of sucking and holding only a central portion of the chip by a collet having a diameter smaller than an external dimension of the chip so that the die-bonding material crawled up to a periphery of the chip will not attach to the lower surface of the collet. However, in this case, the periphery of the upper surface of the chip does not contact with the lower surface of the collet and thus the periphery is prone to warp upwards particularly when load is applied to the die-bonding material while the thinned chip is being sucked and held by the collet (the periphery of the chip warps upwards because a shrinkage ratio of the surface protective film is larger than that of base silicon). As a result, the periphery of the chip and the die-bonding material are not contacted with each other and makes the contact area of the chip and the die-bonding material small; thus, the chip becomes more prone to exfoliate from the wiring board by thermal stress to be applied in a following thermal processing. Moreover, in the case of a chip to which a power MOSFET is formed, an increase in ON resistance is posed.

As a method of applying the die-bonding material to the surface of the wiring board, other than the method of using the multi-point nozzle describe above, there are a method of thinly adhering a die-bonding material to a back surface of a wafer by screen printing, a method of transferring a die-bonding material to a surface of a wiring board using a transferring pin, etc. However, these methods have the following problems, respectively.

First, in the method of printing a die-bonding material to a back surface of a wafer, the die-bonding material is supplied by a predetermined amount (thickness) using a mask (metal mask etc.) for printing. However, when this method is used on recent large-diameter wafers (e.g., φ300 mm wafer etc.), the range of printing is increased and thus variations in thickness of the die-bonding material at the central part and edge part of the wafer are increased; therefore, it becomes difficult to achieve stable printing including management of manufacture.

Next, in the method of transferring a die-bonding material onto a wiring board using a transferring pin, it is impossible to ensure stable transferability according to the following reasons.

For example, Ag pastes are often given suitable viscosity by adding an agent. When such an Ag paste of agent type is backed, the agent vaporizes and the volume of a base material (epoxy-based resin) shrinks, making Ag fillers in the paste more tightly attached (mechanically tangled) and thus there is a characteristic that an electric resistance value is lowered. Such an Ag paste of agent type having this kind of characteristic is very effective in lowering an ON resistance in a chip to which power transistors such as power MOSFETs are formed. However, when the Ag paste of agent type is put into a transferring plate to which a transferring pin is dipped and agitated, the agent vaporizes drying the paste and the transferability is gradually lowered. This means that the transferred amount of products differs at the start and end of transfer and stable production is impossible in manufacturing of semiconductor devices.

A preferred aim of the present invention is to provide technique of die-bonding material application capable of accommodating to thinned chips in manufacture of semiconductor devices having a step of mounting chips onto a wiring board using a paste die-bonding material.

Another preferred aim of the present invention is to provide technique of die-bonding material application capable of suppressing excessive wet spread in manufacture of semiconductor devices having a step of mounting chips onto a wiring board using a paste die-bonding material.

The above and other preferred aims and novel characteristics of the present invention will be apparent from the description of the present specification and the accompanying drawings.

### Means for Solving the Problems

The typical ones of the inventions disclosed in the present application will be briefly described as follows.

A method of manufacturing a semiconductor device which is an embodiment of the present invention includes the steps of :
(a) preparing a wiring board having a chip mounting portion and a plurality of lead terminals arranged to be adjacent to the chip mounting portion and a semiconductor chip to which a plurality of electrode pads and wirings are formed to its main surface;
(b) applying a die-bonding material onto an upper surface of the chip mounting portion of the wiring board;
(c) mounting the semiconductor chip on the upper surface of the chip mounting portion via the die-bonding material so that the upper surface of the chip mounting portion and the main surface of the semiconductor chip are directed to a same direction;
(d) electrically connecting the plurality of electrode pads of the semiconductor chip and the plurality of lead terminals of the wiring board to each other by a conductive material;
(e) forming a sealing body for sealing the semiconductor chip and the conductive material,
the semiconductor chip having a thickness less than half of a thickness of the chip mounting portion, and
the step (b) including filling the die-bonding material being filled in a groove of a nozzle having a groove and transferring the die-bonding material filled in the groove onto the upper surface of the chip mounting portion of the wiring board at an applied thickness smaller than the thickness of the semiconductor chip.

### BRIEF DESCRIPTIONS OF THE DRAWINGS

FIG. 1 is a planar view of a semiconductor device according to a first embodiment of the present invention;

FIG. 2 is a side view of the semiconductor device according to the first embodiment of the present invention;

FIG. 3 is a planar view illustrating a back surface (substrate mounting surface) of the semiconductor device according to the first embodiment of the present invention;

FIG. 4 is a planar view illustrating an inner structure of the semiconductor device according to the first embodiment of the present invention;

FIG. 5 is a cross-sectional view along the line A-A in FIG. 4;

FIG. 6 is a cross-sectional view along the line B-B in FIG. 4;

FIG. 7 is a diagram schematically illustrating a cross-sectional structure of an Ag paste interposed between a back surface of a chip 1 and a die pad;

FIG. 8 is a cross-sectional view of a main part illustrating a structure of a trench gate type n-channel power MOSFET formed on the chip;

FIG. 9A is a planar view illustrating a layout of a gate pad and a source pad formed on a main surface of the chip;

FIG. 9B is a planar view illustrating another example of the layout of the gate pad and the source pad formed on the mains surface of the chip;

FIG. 10 is a planar view illustrating another example of the inner structure of the semiconductor device according to the first embodiment of the present invention;

FIG. 11 is a planar view illustrating another example of the layout of the gate pad and the source pad formed on the main surface of the chip;

FIG. 12 is an entire flow diagram illustrating a method of manufacturing the semiconductor device according to the first embodiment of the present invention;

FIG. 13 is a planar view of a semiconductor wafer to which the power MOSFET is formed;

FIG. 14 is a planar view of a lead frame used in the manufacture of the semiconductor device according to the present invention;

FIG. 15 is a schematic diagram illustrating a main part of a paste applying device used in the manufacture of the semiconductor device according to the first embodiment of the present invention;

FIG. 16A is a planar view of a stamping nozzle loaded to a tip of a syringe of the paste applying device viewed from a lower surface side;

FIG. 16B is a cross-sectional view along the line C1-C1 in FIG. 16A;

FIG. 17A is a planar view illustrating another example of the stamping nozzle;

FIG. 17B is a cross-sectional view along the line C2-C2 in FIG. 17A;

FIG. 18A is a planar view illustrating another example of the stamping nozzle;

FIG. 18B is a cross-sectional view along the line C3-C3 in FIG. 18A;

FIG. 19A is a planar view illustrating another example of the stamping nozzle;

FIG. 19B is a cross-sectional view along the line C4-C4 in FIG. 19A;

FIG. 20A is a planar view illustrating another example of the stamping nozzle;

FIG. 20B is a cross-sectional view along the line C5-05 in FIG. 20A;

FIG. 21A is a planar view illustrating another example of the stamping nozzle;

FIG. 21B is a cross-sectional view along the line C6-C6 in FIG. 21A;

FIG. 22 is a planar view illustrating another example of a planar shape of the chip;

FIG. 23A is a planar view illustrating another example of the stamping nozzle;

FIG. 23B is a cross-sectional view along the line C7-C7 in FIG. 23A;

FIG. 24A is a planar view illustrating another example of the stamping nozzle;

FIG. 24B is a cross-sectional view along the line C8-C8 in FIG. 24A;

FIG. 25A is a planar view illustrating another example of the stamping nozzle;

FIG. 25B is a cross-sectional view along the line C9-C9 in FIG. 25A;

FIG. 26 is a cross-sectional view illustrating a method of applying an Ag paste on a die pad of the lead frame;

FIG. 27 is a cross-sectional view illustrating the method of applying the Ag paste continued from FIG. 26;

FIG. 28 is a cross-sectional view illustrating another example of the method of applying an Ag paste on the die pad of the lead frame;

FIG. 29 is a cross-sectional view illustrating the method of applying the Ag paste continued from FIG. 28;

FIG. 30 is a planar view of the lead frame to which the Ag paste is applied onto the die pad;

FIG. 31 is a cross-sectional view along the line D-D in FIG. 30;

FIG. 32 is a cross-sectional view illustrating a state in which a main surface of a chip is sucked and held by a die-bonding collet;

FIG. 33 is a cross-sectional view illustrating a state in which a back surface of a chip is pressed onto an Ag paste using the die-bonding collet;

FIG. 34 is a planar view illustrating a lead frame immediately after releasing the die-bonding collet from the chip;

FIG. 35 is a planar view illustrating a part of FIG. 34 (the rectangular region denoted by the reference E) in an enlarged manner;

FIG. 36 is a planar view illustrating a leaked amount of an Ag paste when a chip is pressed onto the Ag paste applied onto a die pad using an existing multi-point nozzle method;

FIG. 37 is a planar view illustrating a state in which a gate pad of a chip and a gate post of a lead frame are electrically connected by an Au wire and a source pad of the chip and a source post of the lead frame are electrically connected by an Al ribbon;

FIG. 38 is a planar view illustrating a state in which the source pad of the chip and the source post of the lead frame are electrically connected by an Au wire;

FIG. 39 is a planar view illustrating a state in which the chip is sealed by a mold resin;

FIG. 40 is a cross-sectional view illustrating a method of applying a solder paste onto a die pad of a lead frame;

FIG. 41 is a cross-sectional view illustrating the method of applying a solder paste continued from FIG. 40;

FIG. 42 is a cross-sectional view illustrating the method of applying a solder paste continued from FIG. 41;

FIG. 43 is a cross-sectional view illustrating the method of applying a solder paste continued from FIG. 42;

FIG. 44 is a cross-sectional view illustrating a state in which a main surface of a chip is sucked and held by a die-bonding collet;

FIG. 45 is a cross-sectional view illustrating a state in which mounting of a chip onto a die pad of a lead frame is completed;

FIG. 46 is a planar view illustrating another example of the semiconductor device according to the first embodiment of the present invention;

FIG. 47 is a side view illustrating the another example of the semiconductor device according to the first embodiment of the present invention;

FIG. 48 is a planar view illustrating an inner structure of the another example of the semiconductor device according to the first embodiment of the present invention;

FIG. 49 is a cross-sectional view along the line F-F in FIG. 48; FIG. 50 is a cross-sectional view along the line G-G in FIG. 48;

FIG. 51 is a planar view illustrating an inner structure of a semiconductor device according to a second embodiment of the present invention;

FIG. 52 is an inner equivalent circuit diagram of the semiconductor device according to the second embodiment of the present invention;

FIG. 53 is a planar view illustrating an inner structure of another example of the semiconductor device according to the second embodiment of the present invention;

FIG. 54 is an enlarged cross-sectional view of a die pad and a chip mounted on an upper surface of the die pad illustrated in FIG. 53;

FIG. 55A is a planar view and a cross-sectional view illustrating an example of an existing BGA type semiconductor device;

FIG. 55B is a planar view and a cross-sectional view illustrating an example of the BGS type semiconductor device manufactured by the method of the present invention;

FIG. 56 is a cross-sectional view illustrating a part of the existing BGA type semiconductor device illustrated in FIG. 55A in an enlarged manner;

FIG. 57A is a planar view illustrating an example of a chip-stacking type semiconductor device manufactured in the method of the present invention;

FIG. 57B is a cross-sectional view of the chip-stacking type semiconductor device;

FIG. 58 is a graph illustrating a relationship of frequency of crawling up of a die-bonding material applied onto a wiring board using a multi-point nozzle and a chip thickness; and

FIG. 59 is a cross-sectional view schematically illustrating a situation in which an Ag filler in an Ag paste cuts through a surface protective film and is short-circuited with a metal wiring.

### BEST MODE FOR CARRYING OUT THE INVENTION

Hereinafter, embodiments of the present invention will be described in detail with reference to the accompanying drawings. Note that components having the same function are denoted by the same reference symbols throughout the drawings for describing the embodiment, and the repetitive description thereof will be omitted. In addition, the description of the same or similar portions is not repeated in principle unless particularly required in the following embodiments. Also, in some drawings used in the embodiments, hatching is used even in a plan view so as to make the drawings easy to see.

### First Embodiment

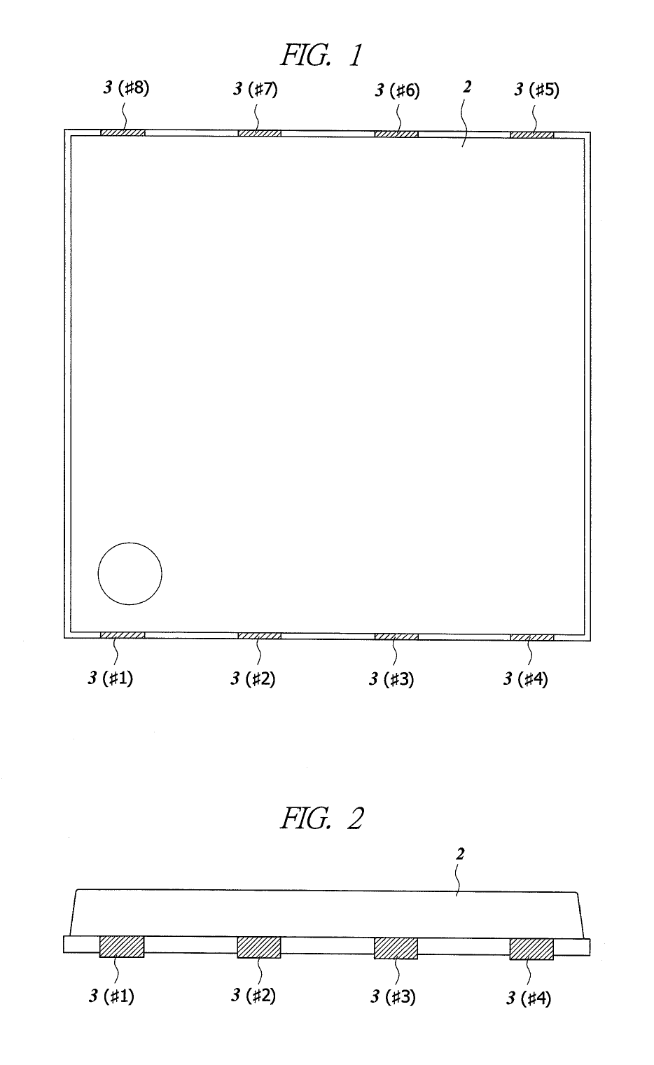

FIGS. 1 to 5 are diagrams illustrating a semiconductor device of the present embodiment, in which FIG. 1 is a planar view, FIG.

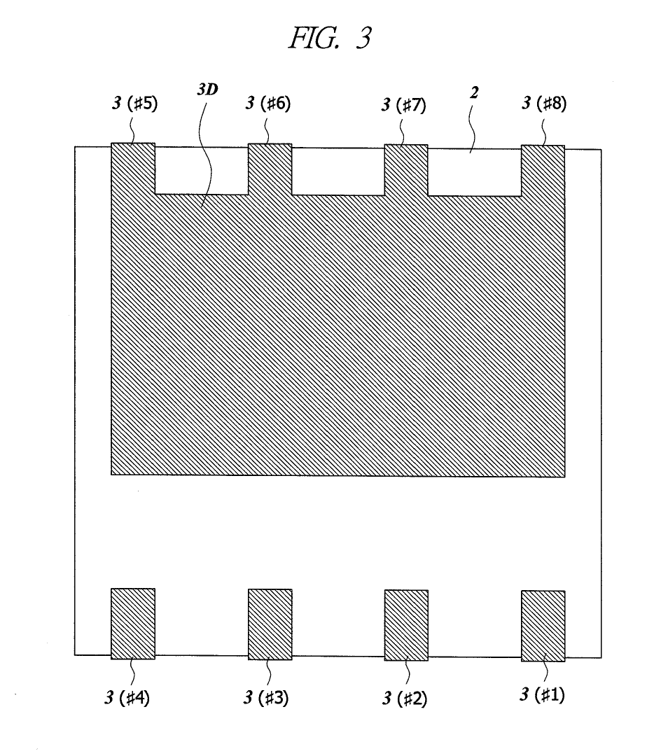

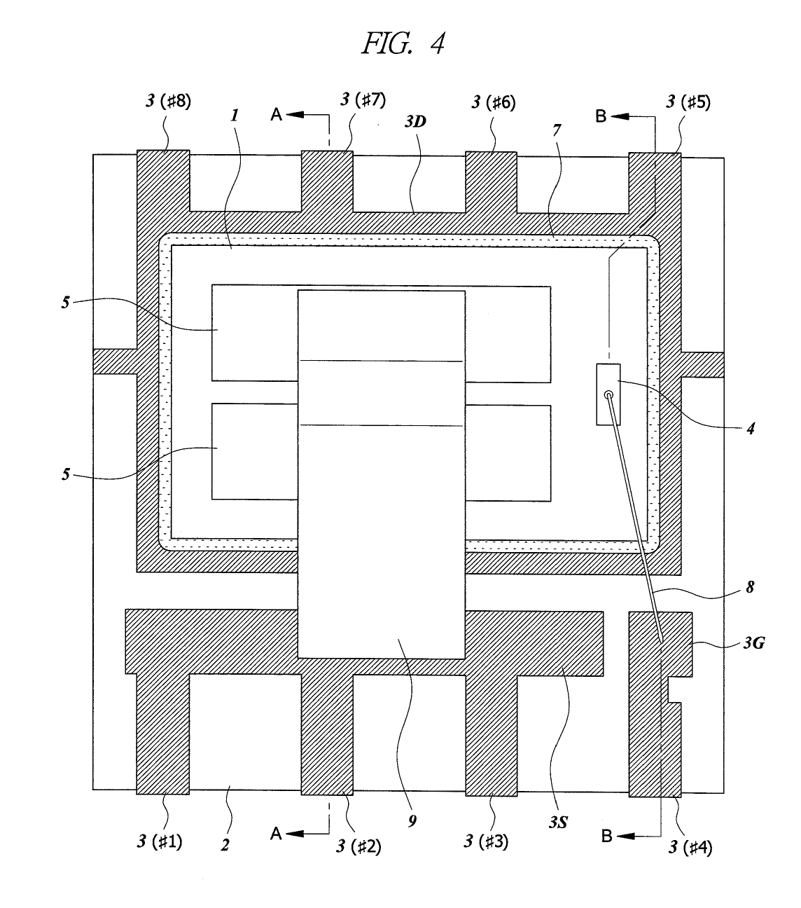

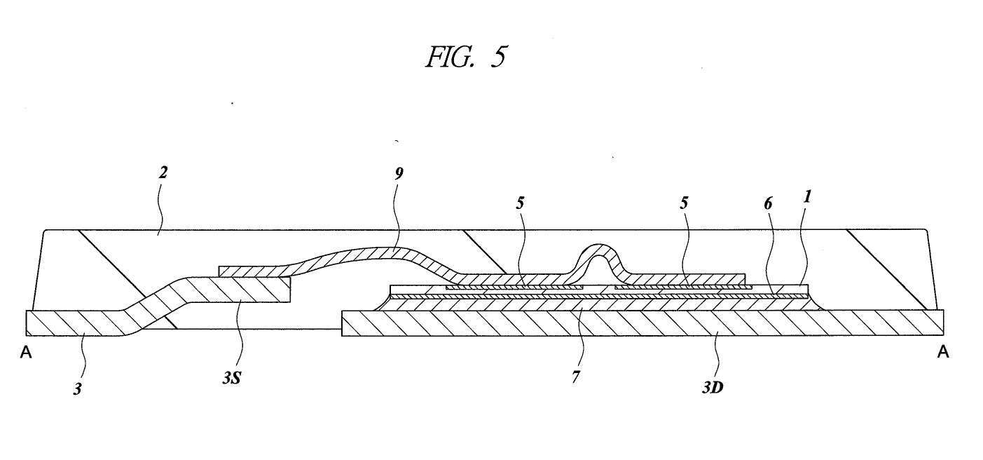

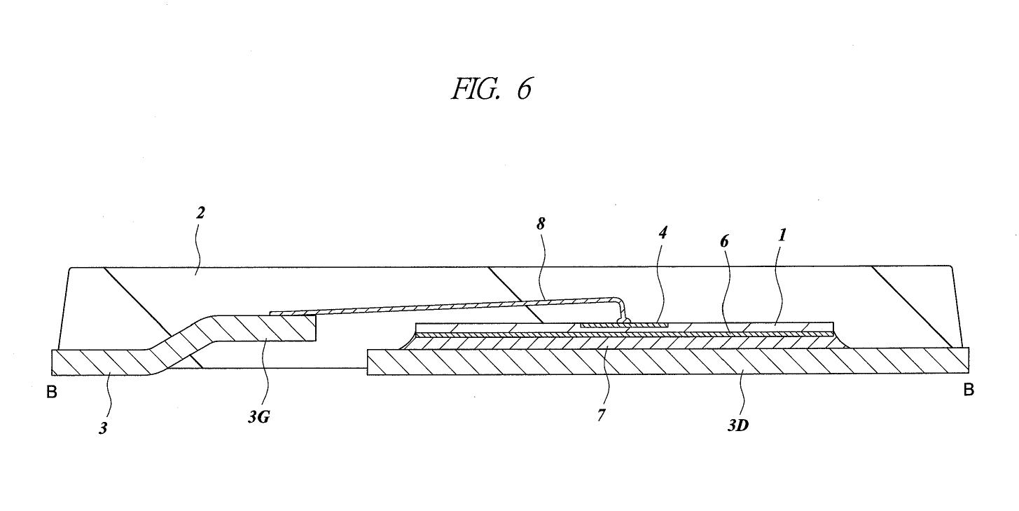

2 is a side view, FIG. 3 is a planar view illustrating a back surface (substrate mounting surface), FIG. 4 is a planar view illustrating an inner structure, FIG. 5 is a cross-sectional view along the line A-A in FIG. 4, and FIG. 6 is a cross-sectional view along the line B-B in FIG. 4.

The semiconductor device of the present embodiment is a small surface-mount package (called FLP: Flat Lead Package) in which a chip 1 mounted on a die pad (chip mounting portion) 3D of a lead frame is sealed by a mold resin 2, and eight leads 3 (#1 to #8) composing external connection terminals of the semiconductor device are exposed in two side surfaces and a back surface (substrate mounting surface) of the mold resin 2. In addition, in the back surface of the mold resin 2, for diffusing heat generated in the chip 1 and reducing thermal resistance of the package, the die pad 3D is exposed together with the eight leads 3. The mold resin 2 is formed of, for example, an insulating material in which a silicon filler is diffused in an epoxy resin that is a type of a thermosetting resin.

Among the eight leads 3 (#1 to #8) describe above, the first lead (#1) to the third lead (#3) are source leads, the fourth lead (#4) is a gate lead, the fifth lead (#5) to the eighth lead (#8) are drain leads. Among these leads 3 (#1 to #8), the three source leads (#1 to #3) are mutually coupled inside the mold resin 2. In addition, the four drain leads (#5 to #8) are integrally formed with the die pad 3D inside the mold resin 2. Hereinafter, the parts of the three source leads (#1 to #3) positioned inside the mold resin 2 (the part of mutual coupling) will be called a source post 3S, and the part positioned inside the mold resin 2 of the gate lead (#5) will be called a gate post 3G.

The leads 3 (#1 to #8) and the die pad 3D are formed of metal plates of such as Cu (copper), Cu alloy, Fe (steel) —Ni (nickel) alloy, and have a thickness of, for example, 200 μm. In addition, plating of three layer structure made by laminating a Ni (nickel) film, a Pd (palladium) film and an Au (gold) film is formed on the surface of the leads 3 (#1 to #8).

The chip 1 mounted on the die pad 3D is formed of single crystal silicon having a main surface to which a plurality of power MOSFETs (described later) used as, for example, power control switches and charge/discharge protect circuit switches in mobile information devices are formed. A common drain for the plurality of power MOSFETs is formed at a back surface of the chip 1. The chip 1 as subject matter of the present invention is a chip having a thickness thinned to be 100 μm or smaller, that is, a thin chip having a thickness that is half of that of the die pad 3D. Although not particularly limited to this, hereinafter, an example in which the thickness of the chip 1 is 50 μm and the thickness of the die pad 3D is 200 μm will be described.

To the main surface of the chip 1, one gate pad 4 electrically connected to a gate electrode of the power MOSFET and two source pads 5 electrically connected to a source of the power MOSFET are formed. The gate pad 4 is electrically connected to the gate post 3G via an Au wire 8. On the other hand, to reduce the ON resistance of the power MOSFET, the two source pads 5 are formed in a larger area than the gate pad 5 and electrically connected to the source post 3S via an Al (aluminum) ribbon 9 having a larger area than the Au wire 8. As described below, the gate pad 4 and the source pad 5 are formed of metal films of such as an Al alloy formed to the uppermost layer of the main surface of the chip 1.

To the back surface composing the drain of the power MOSFET, a drain electrode 6 is formed. The drain electrode 6 is formed of two layers of metal films made by laminating a Ti (titanium) film having a thickness of, for example, 100 nm and an Au film having a thickness of 50 nm. In addition, the drain electrode 6 may be formed of a metal film of three layers made by laminating a Ti film having a thickness of 100 nm, a Ni film having a thickness of 200 nm, and an Au film having a thickness of 100 nm; a metal film of four layers made by laminating a Ni film having a thickness of 50 nm, a Ti film having a thickness of 100 nm, a Ni film having a thickness of 200 nm, and an Au film having a thickness of 100 nm, etc. When the conductive die-bonding material is an Ag paste, any of these metal films is compatible. Also, as the metal film including a Ni film can form a good alloy with Sn in solder (a solder paste is melted), it is compatible to a conductive die-bonding material of a solder paste.

Between the back surface of the chip 1 to which the drain electrode 6 is formed and the die pad 3D, an Ag paste 7 that is a type of conductive die-bonding material is interposed. That is, the back surface of the chip 1 (drain electrode 6) is joined onto an upper surface of the die pad 3D via the Ag paste 7. The Ag paste 7 is, for example, a conductive die-bonding material in which an Ag filler is diffused in an epoxy resin that is a type of thermosetting resin and has an advantage of extremely high heat dissipation property and low ON resistance. Thus, the Ag paste 7 is a die-bonding material suitable to power MOSFET requiring high heat dissipation property and low ON resistance. Note that, space bead is also diffused together with the Ag filler in the Ag paste 7.

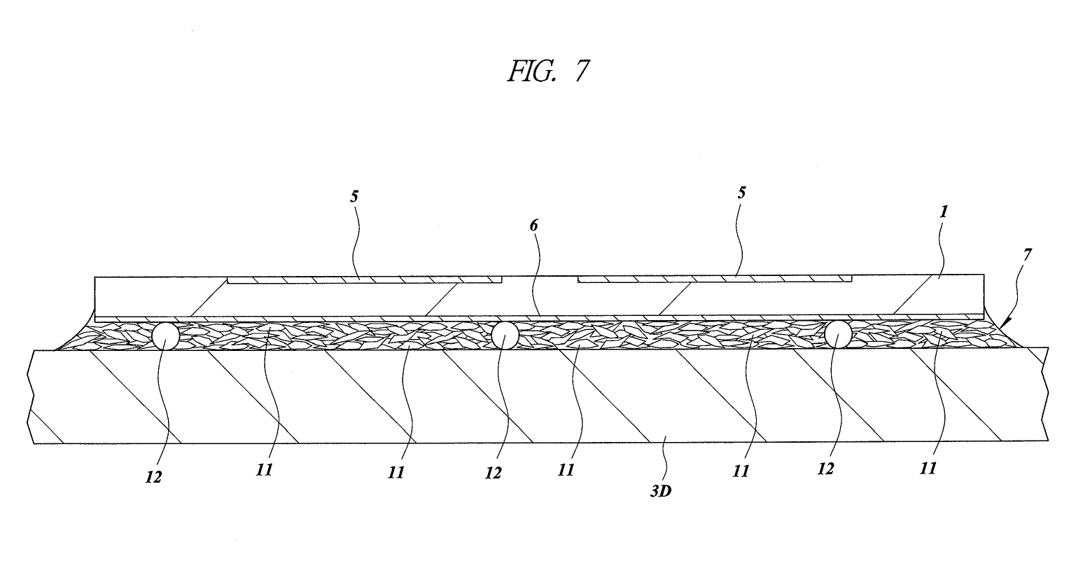

FIG. 7 is a diagram schematically illustrating a cross sectional structure of the Ag paste 7 interposed between the back surface of the chip 1 (drain electrode 6) and the die pad 3D, in which the reference numeral 11 denotes the Ag filler and the reference numeral 12 denotes the spacer bead, respectively.

The Ag paste 7 described above is a die-bonding material of an agent type given a suitable level of viscosity by adding an agent. In the agent type Ag paste 7, the volume of a base material (epoxy resin) shrinks as the agent vaporizes upon baking and the Ag filler 11 diffused in the base material clumps together at a higher density and thus there is a feature that a lower electric resistance value can be obtained as compared with an Ag paste of no-agent type. Thus, by using the Ag paste 7 of agent type as the die-bonding material for joining the chip 1 to which the power MOSFET is formed to the die pad 3D, the ON resistance of the power MOSFET can be reduced as compared to the case of using an Ag paste of no-agent type. Note that, a contained amount of the Ag filler 11 in the Ag paste 7 used in the present embodiment is about 85% before curing and about 95% after curing (after vaporization of the agent). In addition, a size of the Ag filler 11 is, for example, about 2 to 15 μm.

The spacer bead 12 contained in the Ag paste 7 is a spherical object having a diameter of about 15 lam and formed of, for example, a low-elasticity epoxy resin and a contained amount of the spacer bead 12 in the Ag paste 7 is, for example, 15/mm². The spacer bead 12 is added to control the thickness of the Ag paste 7 interposed between the chip 1 and the die pad 3D. That is, by diffusing the spacer bead 12 in the Ag paste 7, even when the thickness of the Ag paste 7 after curing is decreased by evaporation of the agent, a thickness at least about the same level or more of the diameter of the space bead 12 is ensured.

In addition, the spacer bead 12 of a low-elasticity material has a function of mitigating thermal and mechanical stress generated between the chip 1 and the die pad 3D. Particularly, as the amount of heat emission of the power MOSFET which is operated with high power is large, large thermal stress caused by a thermal expansion coefficient between the chip 1 and the die pad 3D is applied to the chip 1 and the die pad 3D. In addition, when the source pad 5 and the source post 3S are electrically connected using the Al ribbon 9 having a wider area than the Au wire 8, large ultrasonic vibration energy is applied between the chip 1 and the die pad 3D upon ribbon bonding. Thus, by adding the spacer bead 12 that is a low-elasticity material in the Ag paste 7, the thermal and mechanical stress as explained above is absorbed or mitigated by the spacer bead 12, thereby suppressing exfoliation of the chip 1 and the die pad 3D.

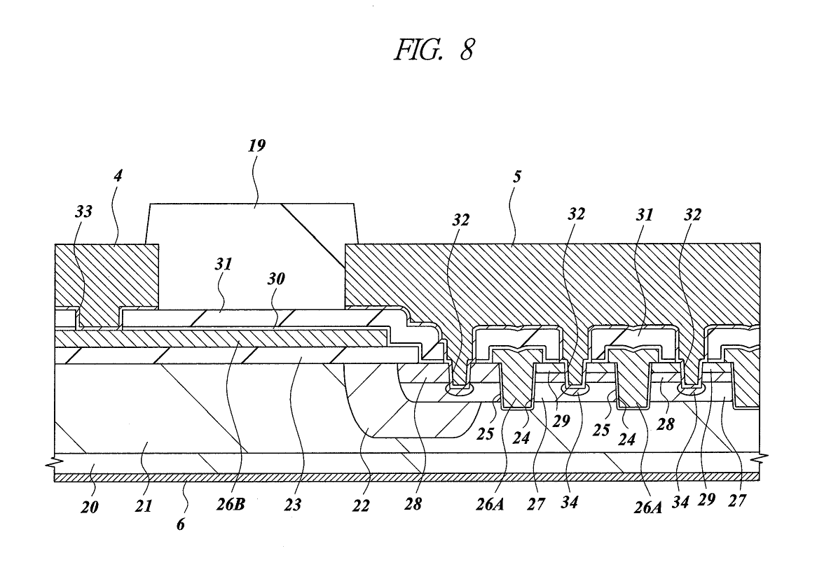

FIG. 8 is a cross-sectional view of a main part illustrating a trench gate type n-channel power MOSFET formed to the chip 1. On a main surface of an n⁺-type single crystal silicon substrate 20, an n⁻-type single crystal silicon layer is formed by epitaxial growth. The n⁺-type single crystal silicon substrate 20 and the n⁻-type single crystal silicon layer 21 form a drain of the power MOSFET.

To a part of the n⁻-type single crystal silicon layer 21, a p-type well 22 is formed. In addition, a silicon oxide film 23 is formed to a part of a surface of the n⁻-type single crystal silicon layer 21, and a plurality of grooves 24 are formed to the other part. In the surface of the n⁻-type single crystal silicon layer 21, a region covered with the silicon oxide film 23 forms a device isolation region; and the region in which the groove 24 is formed forms a device formation region (active region). Although not illustrated, a planar shape of the groove 24 is a polygonal shape such as square, hexagonal and octagon or a stripe extended in one direction.

To a bottom portion and a side wall of the groove 24, a silicon oxide film 25 forming a gate oxide film of the power MOSFET is formed.

In addition, inside the groove 24, a polycrystal silicon film 26A forming a gate electrode of the power MOSFET is formed. Meanwhile, to an upper portion of the silicon oxide film 23, a gate extraction electrode 26B formed of a polycrystal silicon film deposited in the same step as the polycrystal silicon film 26A forming the gate electrode is formed. The gate electrode (polycrystal silicon film 26A) and the gate extraction electrode 26B are electrically connected in a region not illustrated.

To the n⁻-type single crystal silicon layer 21 in the device formation region, a p⁻-type semiconductor region 27 that is shallower than the groove 24 is formed. The p⁻-type semiconductor region 27 forms a channel layer of the power MOSFET. To an upper portion of the p⁻-type semiconductor region 27, a p-type semiconductor region 28 having a higher impurity concentration than the p⁻-type semiconductor region 27 is formed, and, to an upper portion of the p-type semiconductor region 28, an n⁺-type semiconductor region 29 is formed. The p-type semiconductor region 28 forms a punch-through stopper layer of the power MOSFET and the n⁺-type semiconductor region 29 forms a source.

Two silicon oxide films 30 and 31 are formed to an upper portion of the device formation region to which the power MOSFET is formed and to an upper portion of the device isolation region in which the gate extraction electrode 26B is formed. In the device formation region, a connection hole 32, which reaches the p⁻-type semiconductor region 27 by penetrating through the silicon oxide films 30 and 31, the p-type semiconductor region 28 and the n⁺-type semiconductor region 29, is formed. In addition, to the device isolation region, a connection hole 33 reaching the gate extraction electrode 26B by penetrating through the silicon oxide films 31 and 30 is formed.

To an upper portion of the silicon oxide film 31 including the inside of the connection holes 32 and 33, the gate pad 4 and the source pad 5 described above are formed. The gate pad 4 and the source pad 5 are formed of a metal film of stacked layers of, for example, a thin TiW (titanium tungsten) film and a thick Al alloy film. The source pad 5 formed in the device formation region is electrically connected to the source (n⁺-type semiconductor region 29) of the power MOSFET through the connection hole 32. To a bottom portion of the connection hole 32, a p⁺-type semiconductor region 34 for making an Ohmic contact between the source pad 7 and the p-type semiconductor region 27 is formed. Also, the gate pad 4 formed in the device isolation region is connected to the gate electrode (polycrystal silicon film 26A) of the power MOSFET via the gate extraction electrode 26B at a lower portion of the connection hole 33.

An uppermost surface of the chip 1 is covered with a surface protective film 19 except for the regions in which the gate pad 4 and the source pad 5. The surface protective film 19 is formed of a polyimide resin film having a thickness of about 2 μm. Also, to the back surface of the chip 1, that is, to a back surface of the n⁺-type single crystal silicon substrate 20, the drain electrode 6 described above is formed.

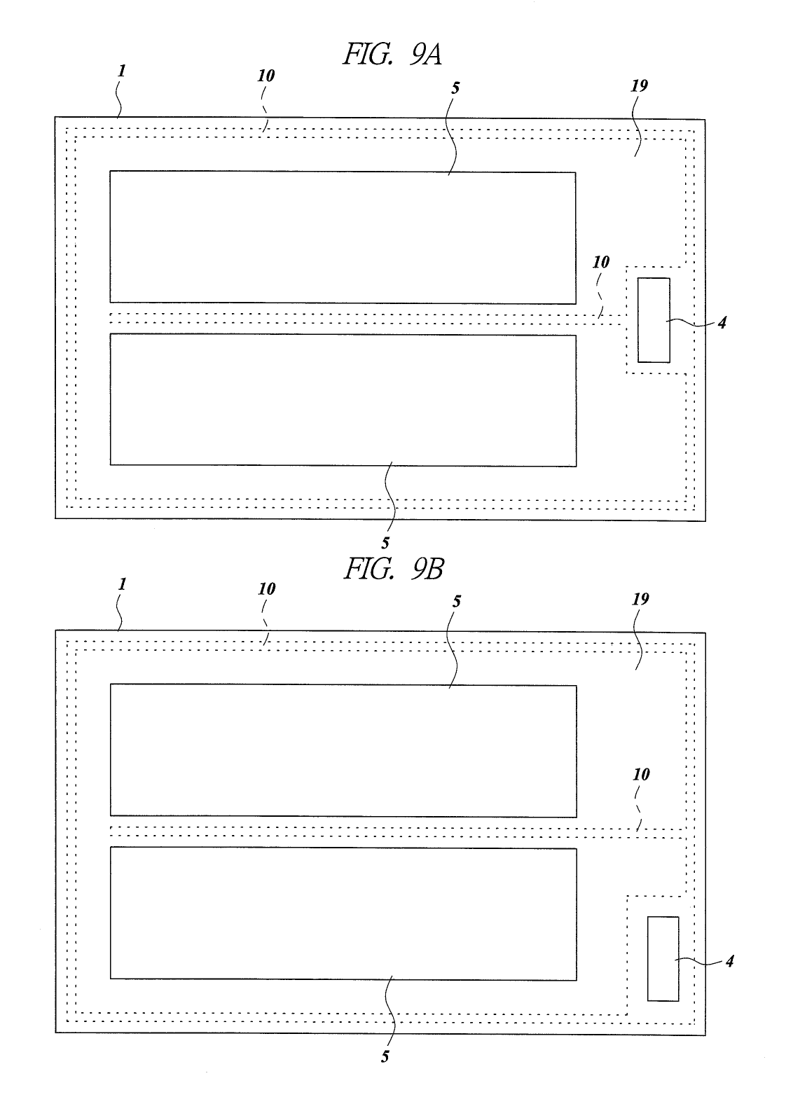

FIG. 9A is a planar view illustrating a layout of the gate pad 4 and the source pad 5 formed to the main surface of the chip 1.

To a peripheral portion and a central portion of the chip 1, a gate extraction electrode 10 is formed. Then, one end of the gate extraction electrode 10 formed to the central portion of the main surface of the chip 1 forms the gate pad 4. In addition, to both sides of the gate extraction electrode 10 formed to the central portion of the main surface of the chip 1, a pair of the source pads 5 is formed. The gate extraction electrode 10, gate pad 4 and source pad 5 are formed of metal films of an Al alloy or the like formed to the uppermost layer of the main surface of the chip 1. As described above, the uppermost layer of the chip 1 is covered with the surface protective film 19 except for the regions in which the gate pad 4 and the source pad 5 are formed and thus the gate extraction electrode 10 is covered with the surface protective film 19.

When the gate pad 4 and the gate extraction electrode 10 are arranged in the main surface of the chip 1 in the above-described manner, one end of the gate electrode (polycrystal silicon film 26A) of each of the power MOSFETs illustrated in FIG. 8 extends in straight line toward the gate extraction electrode 10 and electrically connected to the gate extraction electrode 10. In this manner, lengths of the gate electrodes (polycrystal silicon film 26A) can be substantially uniform in the whole region of the main surface of the chip 1 and thus switching property of the power MOSFET is improved.

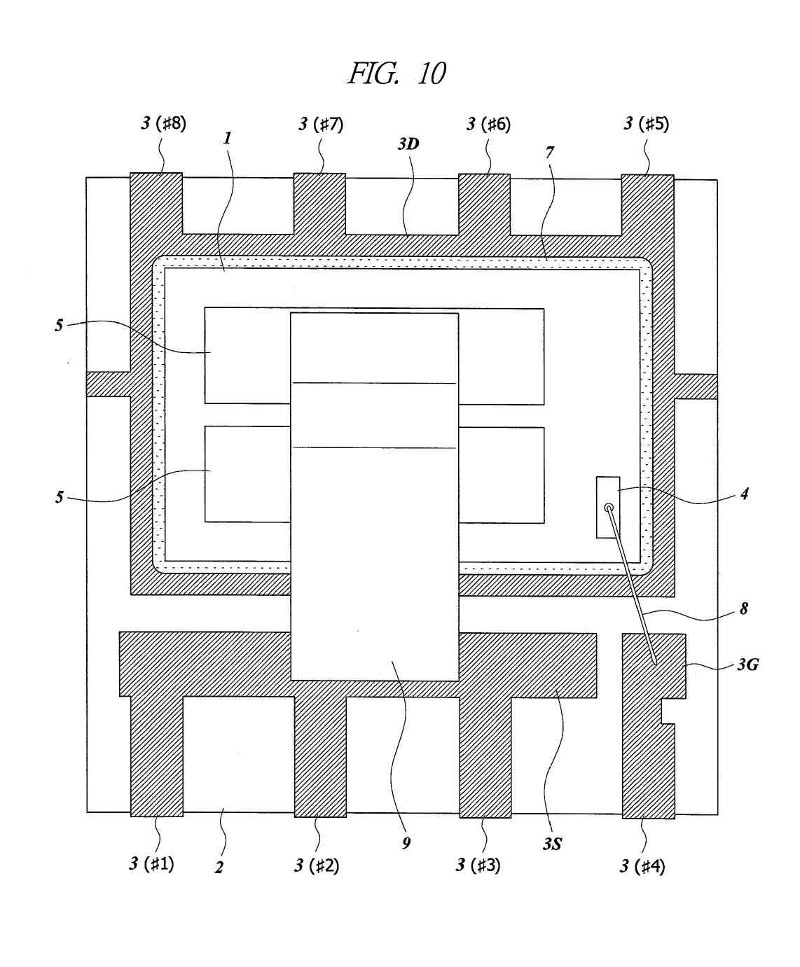

Note that, as illustrated in FIG. 9B, the gate pad 4 may be arranged in a corner portion of the main surface of the chip 1. In this manner, a length of the Au wire 8 connecting the gate pad 4 and the gate post 3G can be shorter than that in the layout illustrated in FIG. 9A (see FIGS. 4 and 10).

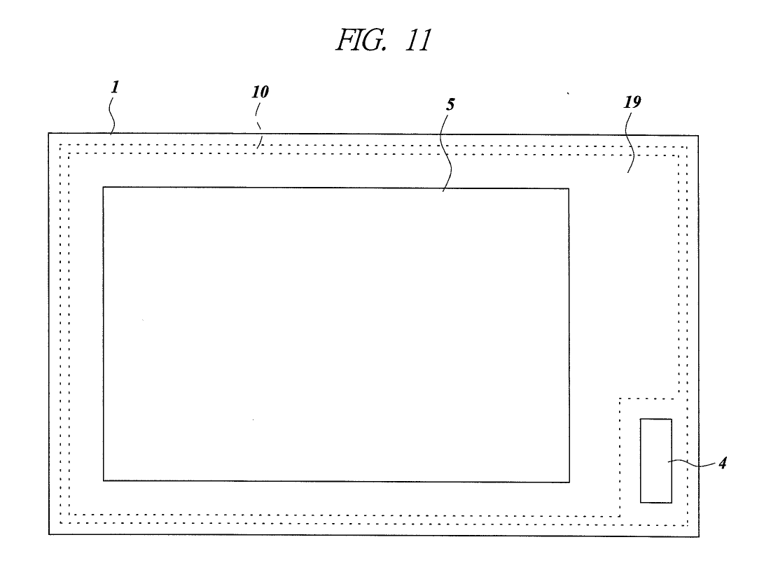

In addition, the layout of the source pad 5 is not limited to that illustrated in FIGS. 9A and 9B either. For example, as illustrated in FIG. 11, the gate extraction electrode 10 may arranged only in an outer periphery portion of the main surface of the chip 1 and one source pad 5 may be arranged in the central portion. In this manner, the area of the source pad 5 can be large and thus the ON resistance of the power MOSFET can be further reduced.

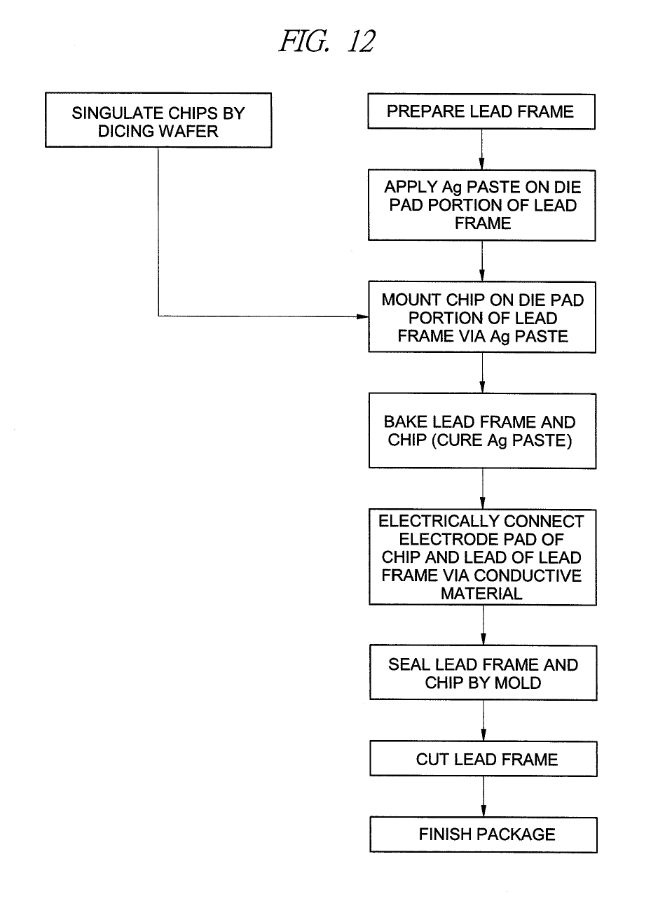

Next, a method of manufacturing a small surface-mount package formed in the above-described manner will be described. FIG. 12 is an entire flow chart illustrating the method of manufacturing the small surface-mount package according to the present embodiment.

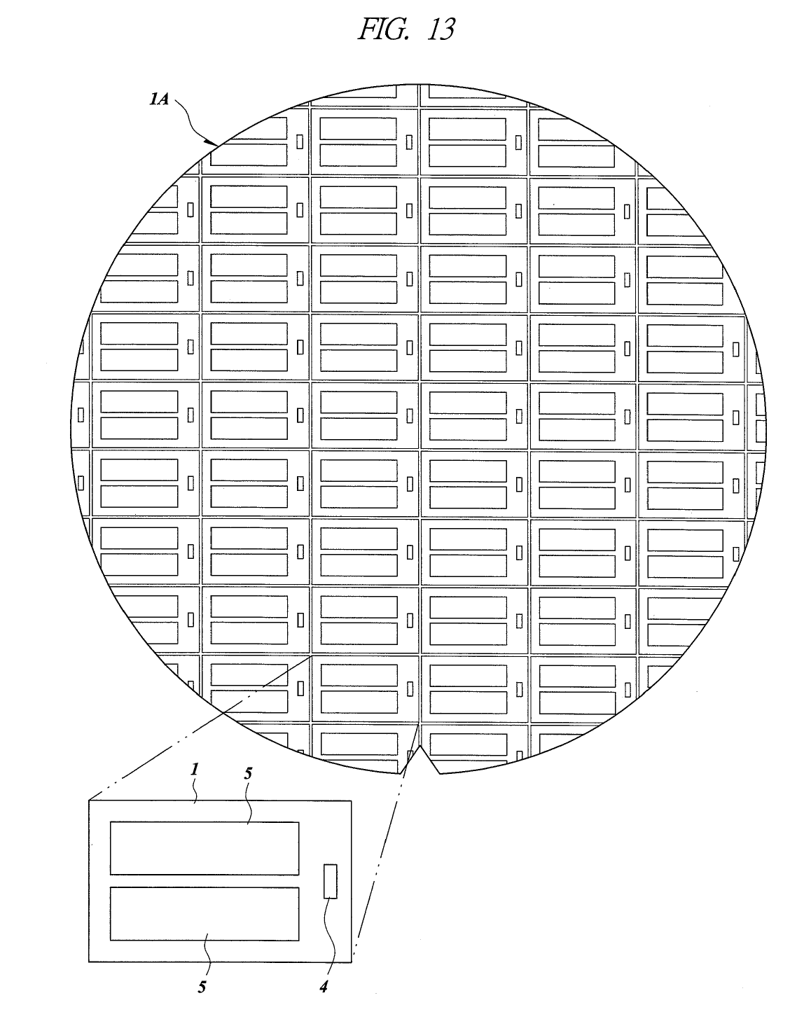

To manufacture the small surface-mount package, after forming the power MOSFET described above to a main surface of a semiconductor wafer 1A illustrated in FIG. 13 using a semiconductor wafer manufacturing process, a back surface of the wafer is polished to make a thickness of the semiconductor 1A thin until 50 μm here. Next, after forming the drain electrode 6 described above to the semiconductor wafer 1A, the semiconductor wafer 1A is diced to obtain a plurality of chips 1.

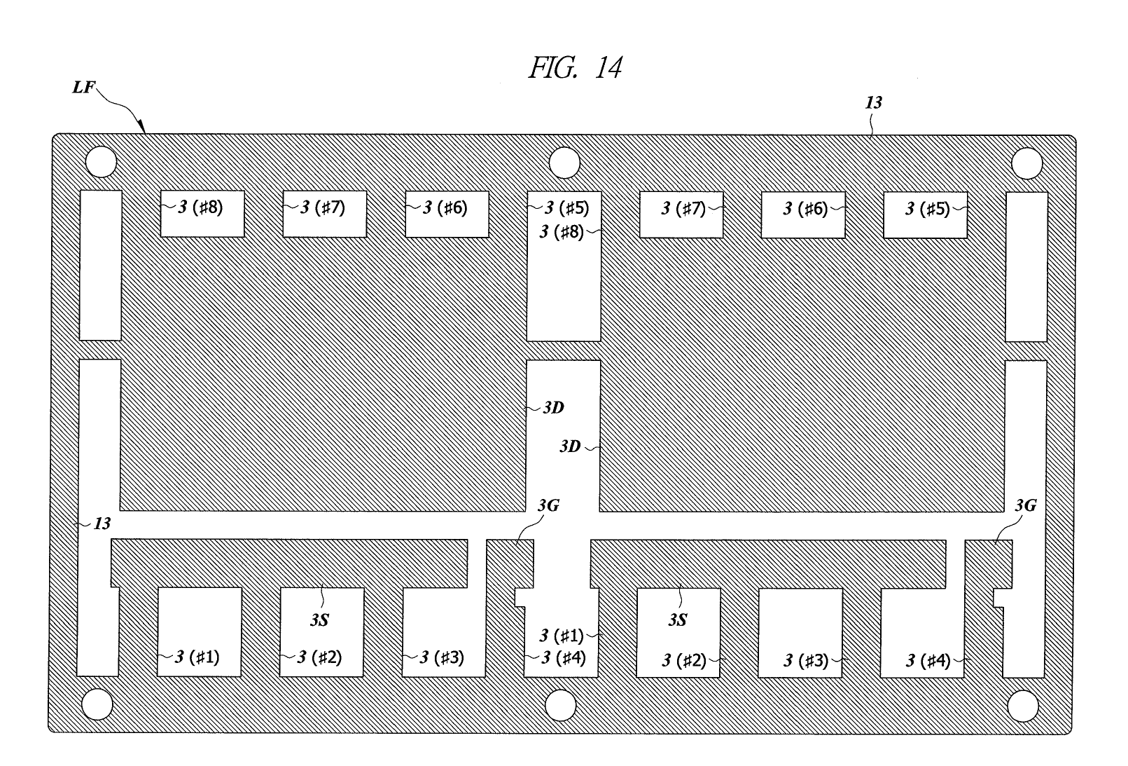

In addition, at the same time with the above-described work, the lead frame LF illustrated in FIG. 14 is prepared. The lead frame LF has a structure in which the leads 3 (#1 to #8) described above and the die pad 3D are supported by the rectangular frame 13 and a thickness of the lead frame LF is 200 μm here. Further, the fourth lead (#4) forming the gate lead and the first lead (#1) to the third lead (#3) forming the source leads are bent in a predetermined shape (see FIGS. 5 and 6). Note that, although the actual lead frame has a structure in which a plurality of die pads 3D are arranged in matrix inside the frame 13, an example of the lead frame LF having two die pads 3D will be described here to facilitate viewing of the drawings.

Next, the Ag paste 7 described above is applied onto the die pad 3D of the lead frame LF. In the present embodiment, as a method of applying the Ag paste 7 onto the die pad 3D, stamping method, which will be described in detail below, is used.

FIG. 15 is a schematic diagram illustrating a main part of a paste applying apparatus 40. The paste applying apparatus 40 includes: a syringe 41 in which the Ag paste 7 in a not-cured state; and a stamping nozzle 42 attached to a tip (lower end) of the syringe 41. The syringe 41 is supported by an arm 44 attached to a driving unit 43 and shifted in a horizontal direction (XY direction) and a vertical direction (Z direction) by a motor embedded in the driving unit 43.

To the syringe 41, air of a predetermine amount is supplied from an air supply source not illustrated through a pipe 45 connected to an upper end portion of the syringe 41. In addition, a piston 46 is inserted to the inside of the syringe 41 and the Ag paste 7 for a predetermined amount corresponding to the supplied amount of the air is transferred from the syringe 41 to the stamping nozzle 42 as the piston 46 goes downward by the pressure of the air supplied inside the syringe 41.

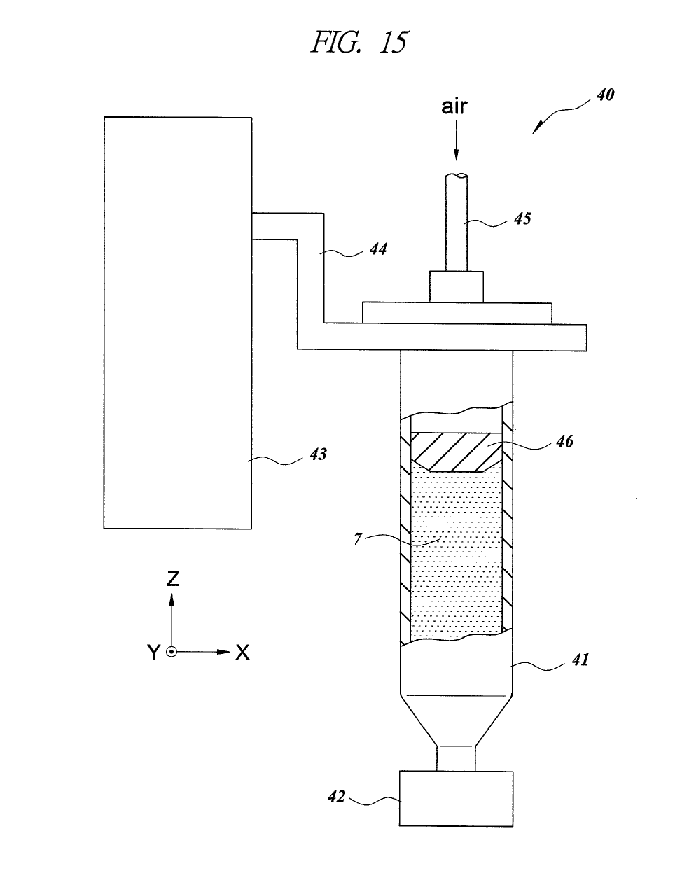

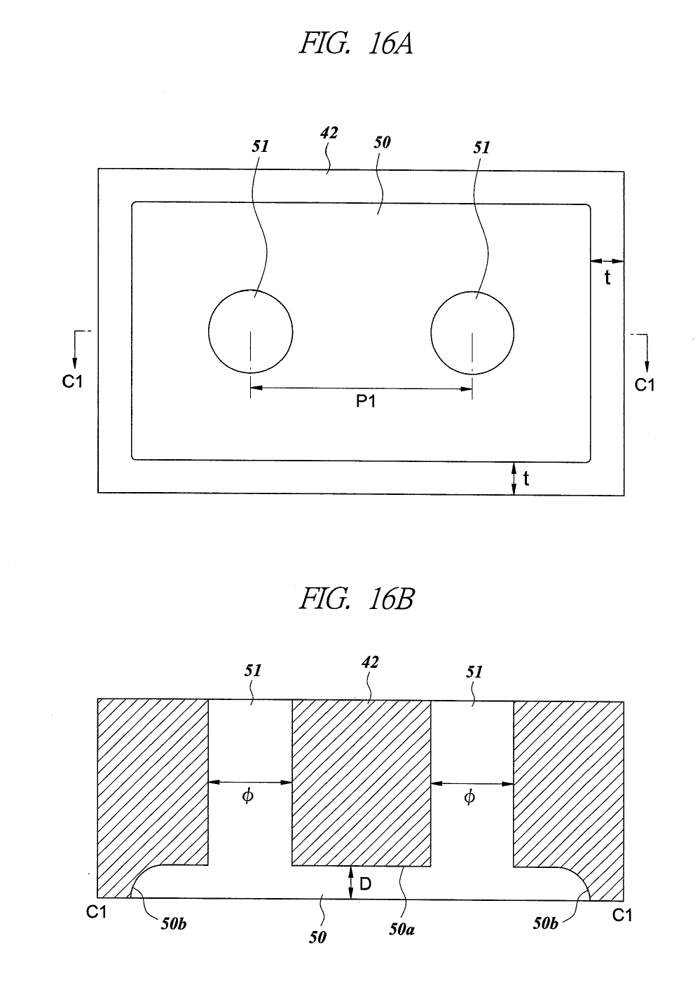

FIG. 16A is a planar view of the stamping nozzle 42 attached to the tip of the syringe 41 viewed from a lower surface side, and FIG. 16B is a cross-sectional view along the line C1-C1 in FIG. 16A.

The stamping nozzle 42 is formed of a corrosion-resistant metal such as stainless-steel and a planar shape of the lower surface side of the stamping nozzle 42 is rectangle. To the lower surface of the stamping nozzle 42, a dug portion (holding portion, accumulating portion, space portion) 50 to be a space in which the Ag paste 7 is filled is provided. The stamping nozzle 42 is attached to the syringe 41 so that the center of the dug portion 50 coincides with the center of the tip (Ag paste discharging portion) of the syringe 41.

A planar shape of the dug portion is rectangular and a ratio of a longer side and a shorter side is substantially the same as a ratio of a longer side and a shorter side of the chip 1. In addition, planar dimensions of the dug portion 50 are smaller than external dimensions of the chip 1 by about 100 to 500 μm at one side. Further, a thickness (t) from an outer rim of the dug portion 50 to a side surface of the stamping nozzle 42 is preferable to be 200 to 500 μm. When the thickness (t) is ensured to this level, influence on the lifetime of the stamping nozzle 42 is small. Moreover, by making the external dimensions of the lower surface of the stamping nozzle 42 about an addition of the external dimension of the chip 1 and 100 μm on one side, it is possible to reduce possibility of interference between the stamping nozzle 42 and its surrounding during work.

A depth (D) of the dug portion 50 is smaller than the thickness of the chip 1 (=50 μm). However, upon transferring the Ag paste 7 filled in the dug portion 50 onto the die pad 3D of the lead frame LF, to prevent crashing of the spacer bead 12 in the Ag paste 7, the depth (D) of the dug portion 50 is preferable to be larger than the diameter of the spacer bead 12. As described above, since the diameter of the spacer bead 12 is about 15 μm, D=20 μm is used here.

The dug portion 50 has: a dug surface 50a positioned above the lower surface of the stamping nozzle 42; and four sidewalls 50b surrounding the dug surface 50a. The dug surface 50a and the sidewalls 50b are finished by smooth mirror style without concavity and convexity. Also, as illustrated in FIG. 16B, a region in which the dug surface 50a and the sidewalls 50b respectively cross is in an “R” shape. In this manner, the demolding property of the Ag paste 7 in the dug portion 50 to an inner wall (the dug surface 50a and the sidewalls 50b) is improved and troubles such as sticking of the Ag paste 7 to the inner wall of the dug portion 50 and residue of the Ag filler 11 and the spacer bead 12 in the Ag paste 7 inside the dug portion 50 can be improved; thus, variations in applied amount of the Ag paste 7 transferred onto the die pad 3D can be reduced.

Above the dug portion 50, a pair of flow paths 51 for transferring the Ag paste 7 in the syringe 41 to the dug portion 50 is provided. A lower end of each of the flow paths 51 is positioned at the dug surface 50a. Thus, when the dug surface 51a is viewed in plane from the lower surface side of the stamping nozzle 42, the flow paths are recognized as openings.

The two flow paths (openings) 51 provided to the stamping nozzle 42 are arranged at positions at an even distance along the longitudinal direction from the center of the dug portion 50 and also on a line connecting the centers of two short sides to each other. In addition, a pitch (P1) of the two flow paths 51 is preferable to be about one third to half of a length of a longer side of the dug portion 50.

While a planar shape of the flow paths 51 can be circular or rectangular, to suppress variations of discharged amount occurring due to catching of the Ag filler 11 and the spacer bead 12 in the Ag paste 7 inside the flow paths 51, the planar shape of the flow paths 51 is preferable to be circular as illustrated in FIG. 16A. Also, an opening size (φ) of the flow paths 51 is preferable not to let the Ag paste 7 drip during standby and not to pose clogging by the Ag filler 11 and the spacer bead 12. More specifically, φ=300 to 400 μm is preferable and φ=350 μm is used here.

The number of the flow paths 51 provided to the stamping nozzle 42 is not limited to two and it is desirable to optimize the number suitably in accordance with the external dimensions of the chip 1 or the ratio of the longer side and the shorter side. When the external dimensions of the chip 1 are small, the number of the flow paths 51 may be one. Particularly, when the external dimensions of the chip 1 are large, by providing three or more flow paths 51 to the stamping nozzle 42, a trouble of lacking of the filled amount of the Ag paste 7 in a vicinity of corner portions of the dug portion 50 can be improved.

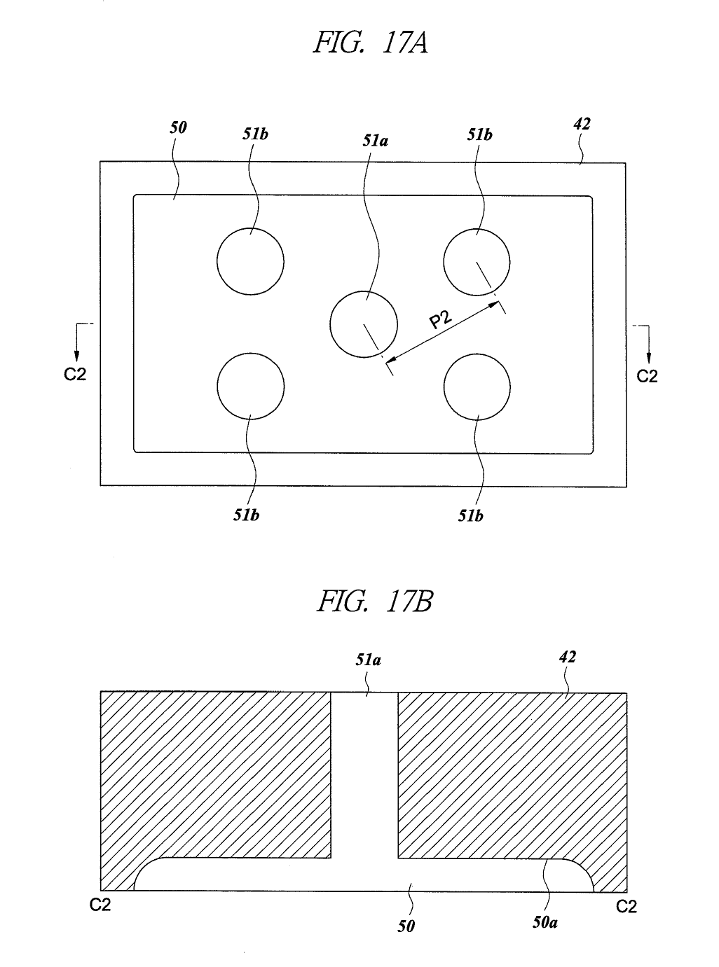

FIGS. 17A and 17B are an example of providing five flow paths 51 to the stamping nozzle 42. Here, the five flow paths 51 are arranged on diagonal lines connecting the corner portions of the dug portion 50 to each other, and center of the diagonal lines coincides with the center of the dug portion 50 (=the center of the tip of the syringe 41). One flow path 51a is arranged at the center of the dug portion 50 and the other four flow paths 51b are arranged to surround the flow path 51a and also arranged in the vicinity of the corner portions of the dug portion 50. A pitch (P2) between the flow path 51a arranged at the center of the dug portion 50 and the flow paths 51b arranged around the flow path 51a is preferable to be about one third to half of a length of the diagonal lines.

In this manner, as the stamping nozzle 42 illustrated in FIGS. 17A and 17B has the flow paths 51b arranged in the vicinity of the corner portions of the dug portion 50, the filled amount of the Ag paste 7 at the corner portion can be stable.

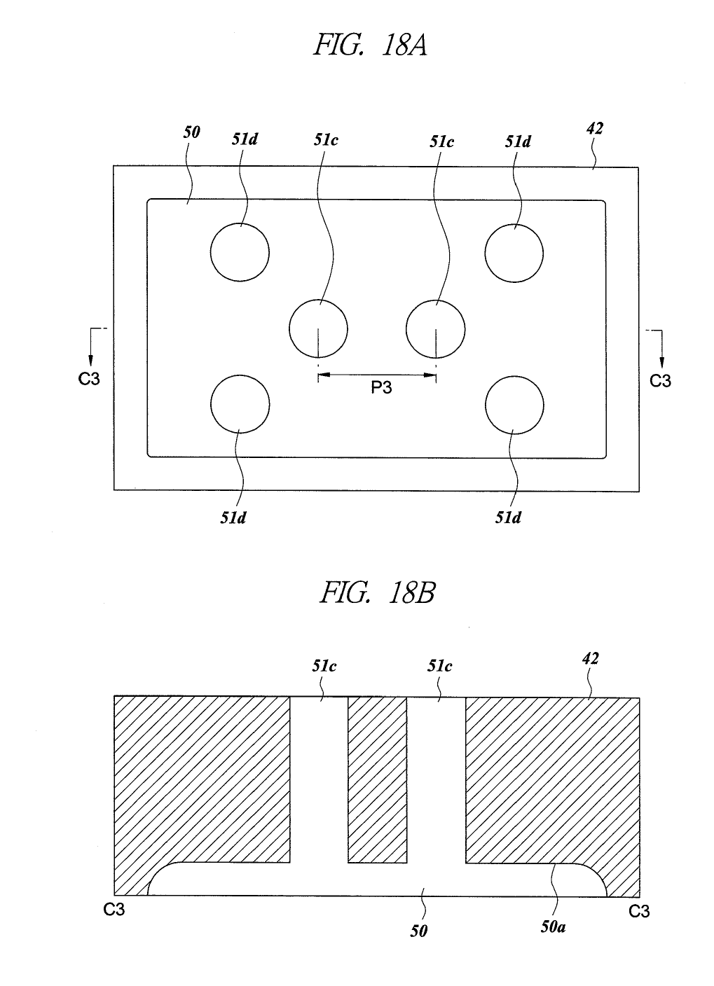

FIGS. 18A and 18B are an example of providing six flow paths 51 to the stamping nozzle 42. Here, two flow paths 51c arranged near the center of the dug portion 50 are arranged at positions at an even distance from the center of the dug portion 50 in the longitudinal direction and also arranged on the central line of the shorter side of the dug portion 50. A pitch of the two flow paths 51c is preferable to be quarter or less than quarter of the length of the longer side of the dug portion 50. On the other hand, four flow paths 51d are arranged on diagonal lines connecting the corner portions of the dug portion 50 and a distance from the center of the dug portion to each of the flow paths 51d is identical. Moreover, a distance from the center of the dug portion 51 to each of the flow paths 51c is preferable to be quarter or more than quarter of the length of the diagonal line.

As the stamping nozzle 42 illustrated in FIGS. 18A and 18B has the two flow paths 51c on the central line of the shorter side of the dug portion 50, even when the shape of the chip 1 is narrow and long and the dug portion 50 is accordingly in a narrow and long shape, the Ag paste 7 can be more stably filled in the dug portion 50 than the stamping nozzle 42 illustrated in FIGS. 17A and 17B.

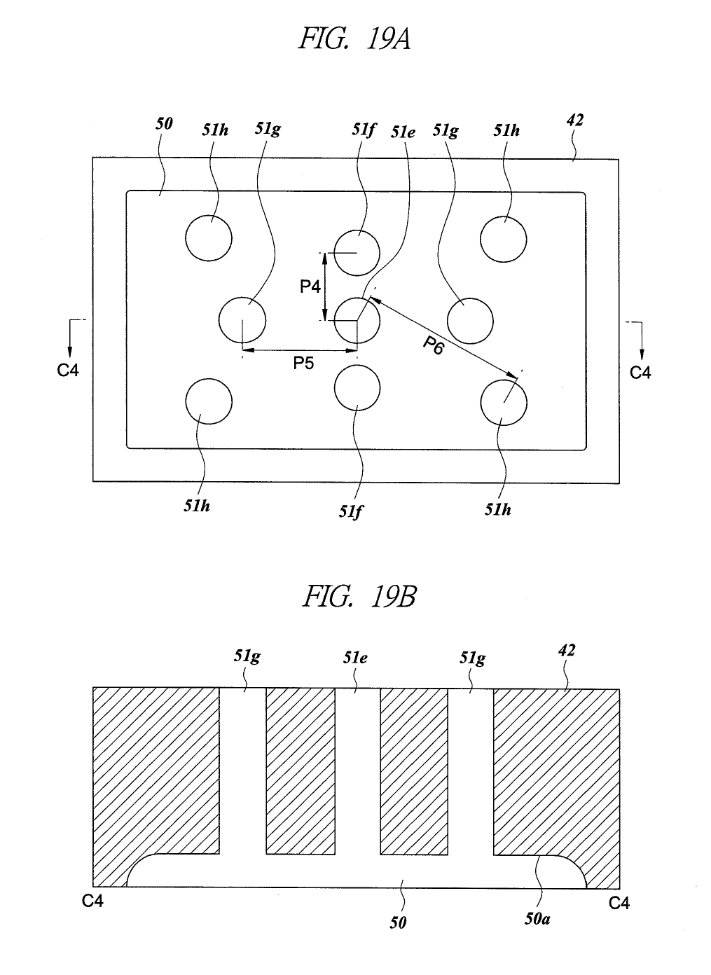

FIGS. 19A and 19B are an example of providing nine flow paths 51 to the stamping nozzle 42. Here, a center of the nine flow paths 51 coincides with the center of the dug portion 50 and one flow path 51e is arranged at the center. Also, two flow paths 51f are arranged on lines connecting a center of one of longer sides of the dug portion 50 and a center of the other one of the longer sides; and two flow paths 51g are arranged on a line connecting a center of one of the shorter sides of the dug portion 50 and a center of the other one of the shorter sides. Moreover, the rest of four flow paths 51h are arranged on diagonal lines connecting the corner portions of the dug portion 50 to each other.

A pitch (P4) of the flow paths 51e and the flow paths 51f is preferable to be quarter or less than quarter of the length of the shorter side of the dug portion 50. Also, a pitch (P5) of the flow path 51e and the flow paths 51g is preferable to be quarter or less than quarter of the length of the longer side of the dug portion 50. Moreover, a pitch (P6) of the flow path 51e and the flow paths 51h is preferable to be quarter or more of the length of the diagonal line.

In the stamping nozzle illustrated in FIGS. 19A and 19B, as the two flow paths 51f are arranged on the line connecting the center of one of the longer sides of the dug portion 50 and the center of the other one of the longer sides; the two flow paths 51g are arranged on the line connecting the center of one of the shorter sides of the dug portion 50 and the other one of the shorter sides; and the four flow paths 51h are arranged on the diagonal lines connecting the corner portions to each other, even when the external dimensions of the chip 1 is large, the Ag paste 7 can be more stably filled in the dug portion 50 than the stamping nozzle 42 illustrated in FIGS. 17A and 17B.

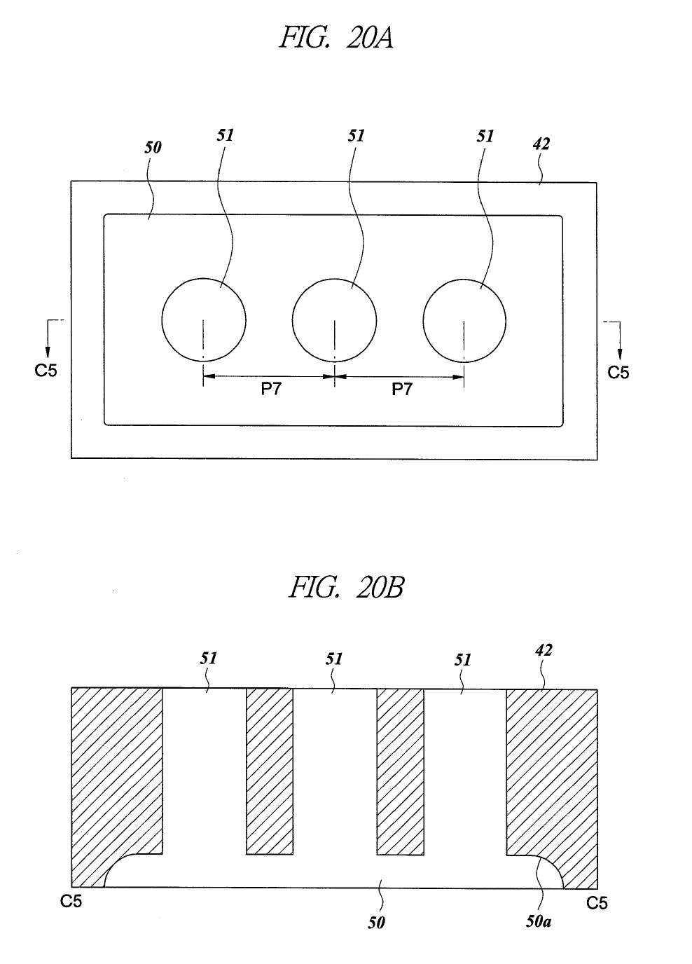

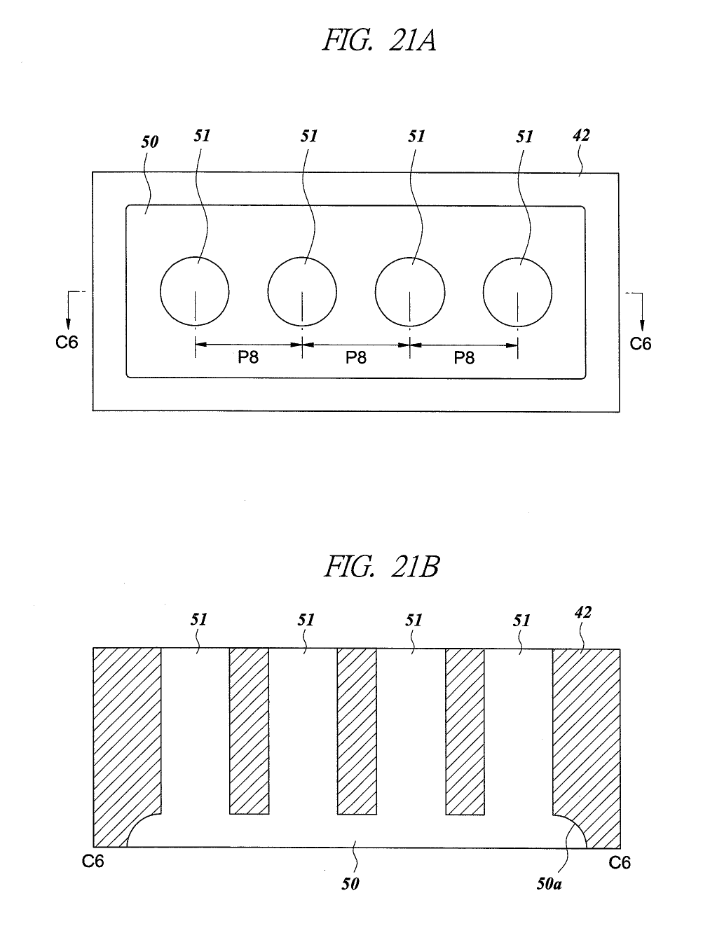

FIGS. 20A and 20B are an example of providing three flow paths 51 in line along the longitudinal direction of the dug portion 50; and FIGS. 21A and 21B are an example of providing four flow paths 51 in line along the longitudinal direction of the dug portion 50. These examples are structures suitable when the ratio of the length of the longer side to the length of the shorter side of the dug portion 50 is large.

In the example illustrated in FIGS. 20A and 20B, the three flow paths 51 are arranged on the line connecting the center of one of the shorter sides of the dug portion and the center of the other one of the shorter sides, in which the flow path 51 at the center is arranged at the center of the dug portion 50. Moreover, a pitch (P7) of the neighboring flow paths 51 is preferable to be about one third of the length of the longer side of the dug portion 50.

In the example illustrated in FIGS. 21A and 21B, the four flow paths 51 are arranged on the line connecting the center of one of the shorter sides of the dug portion and the center of the other one of the shorter sides, and a center of the four flow paths 51 coincides with the center of the dug portion 50. Moreover, a pitch (P8) of the neighboring flow paths is preferable to be about quarter of the length of the longer side of the dug portion 50.

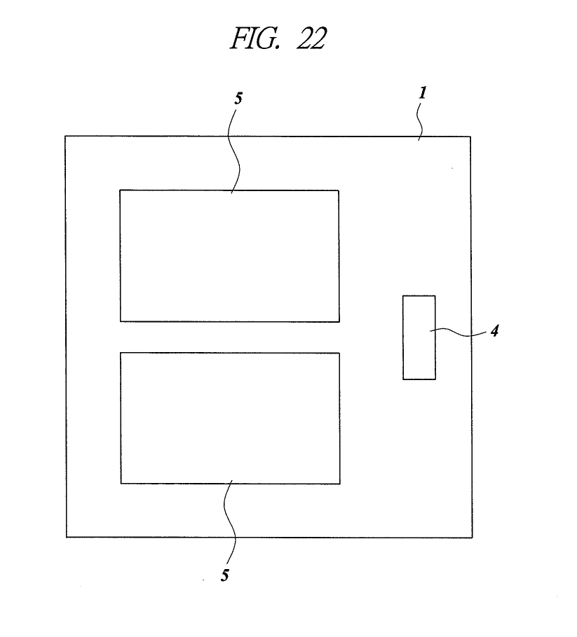

The stamping nozzle 42 illustrated in FIGS. 16A to 21B is used when the planar shape of the chip 1 is rectangular; however, when the planar shape of the chip 1 is square as illustrated in FIG. 22, it is desired to use the stamping nozzle 42 having the planar shape of the dug portion 50 being square.

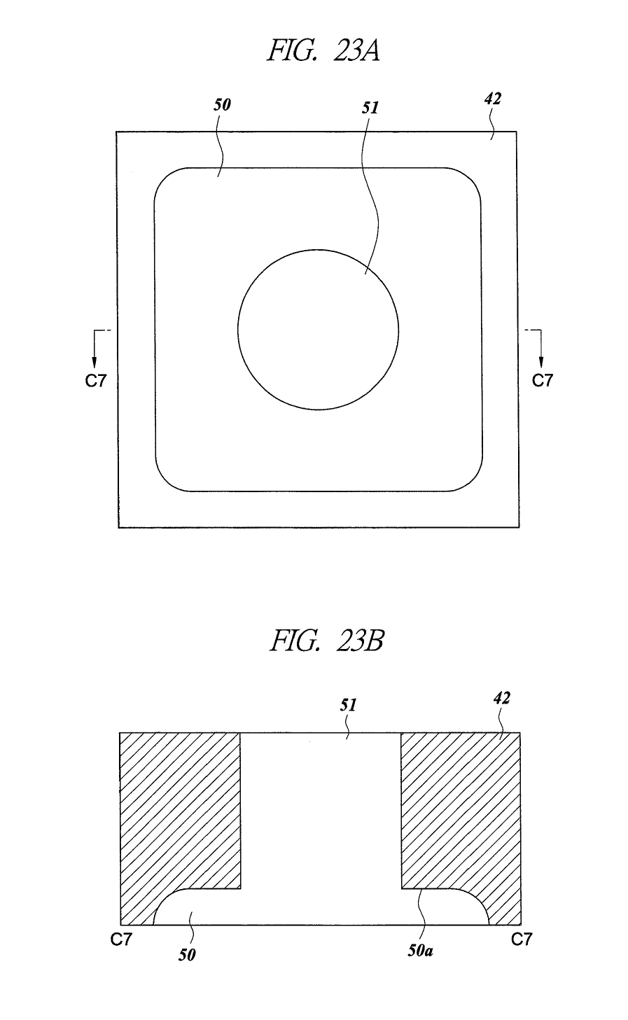

FIGS. 23A and 23B are an example of providing one flow path 51 to the stamping nozzle 42 having the planar shape of the dug portion 50 in a square shape. Here, the flow path 51 is arranged at the center of the dug portion 50 (=the center of the tip of the syringe 41).

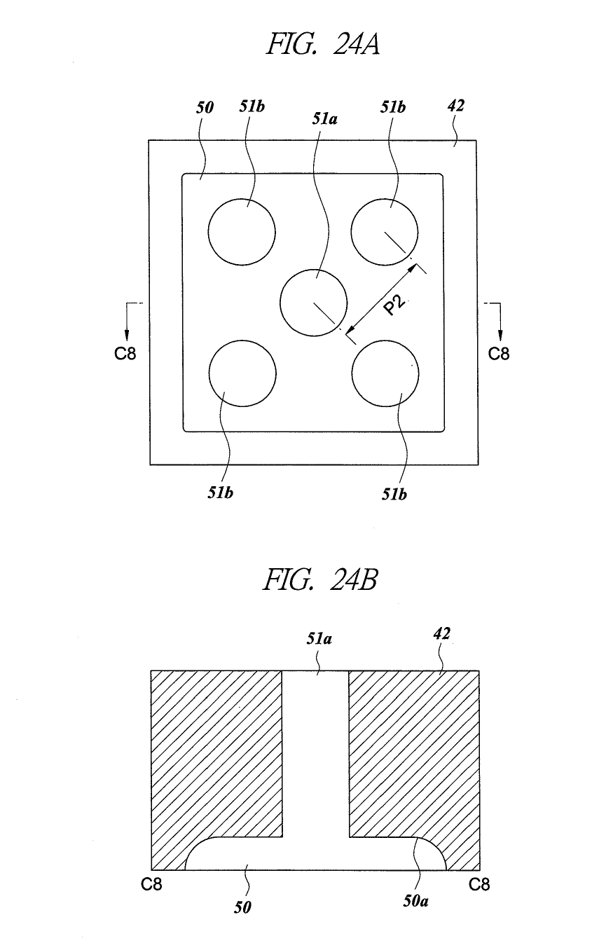

FIGS. 24A and 24B are an example of providing five flow paths 51 to the stamping nozzle 42 having the planar shape of the dug portion 50 in a square shape. In the same manner as the example illustrated in FIGS. 17A and 17B, the five flow paths 51 are arranged on the diagonal lines connecting the corner portions of the dug portion 50 to each other and a center of them coincides with the center of the dug portion 50. Moreover, the pitch (P2) between the flow path 51a arranged at the center of the dug portion 50 and the flow paths 51b surrounding the flow path 51a is preferable to be about one third to half of the length of the diagonal line.

As the stamping nozzle 42 illustrated in FIGS. 24A and 24B has, in the same manner as the example illustrated in FIGS. 17A and 17B, the flow paths 51b arranged in the vicinity of the corner portions of the dug portion 50, the filled amount of the Ag paste 7 at the corner portions can be more stable than the stamping nozzle 42 illustrated in FIGS. 23A and 23B.

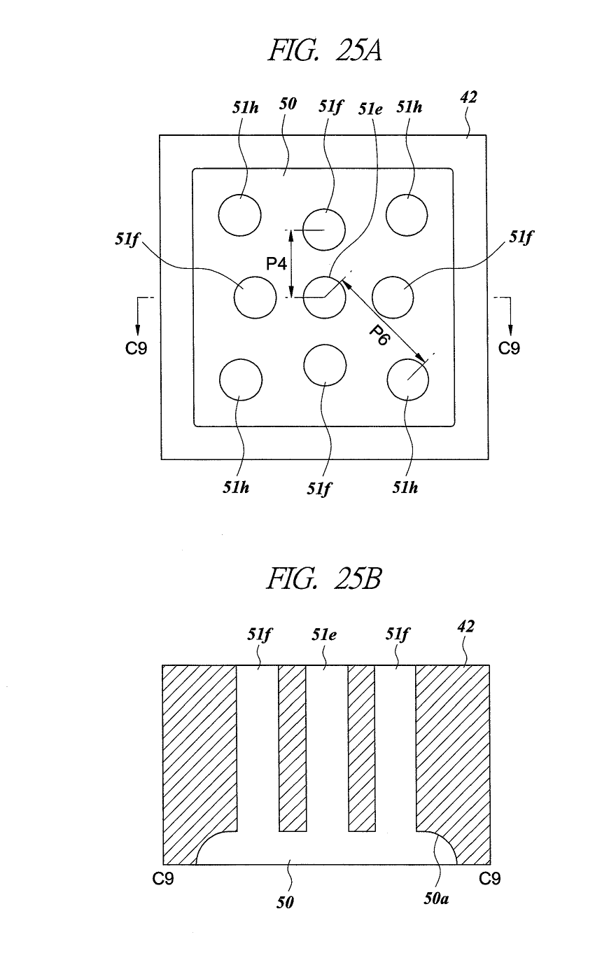

FIGS. 25A and 25B are an example of providing nine flow paths 51 to the stamping nozzle 42 having the planar shape of the dug portion 50 in a square shape. Here, a center of the nine flow paths coincides with the center of the dug portion 50 and one flow path 51e is arranged at the center. Also, four flow paths 51f are arranged on the line connecting the center of the dug portion 50 and a center of one side of the dug portion 50 and the rest of four flow paths 51h are arranged on the diagonal lines connecting the corner portions of the dug portion 50 to each other. The pitch (P4) of the flow path 51e and the flow paths 51f is preferable to be about one sixth to quarter of the length of the one side of the dug portion 50 and the pitch (P6) of the flow path 51e and the flow paths 51h is preferable to be the pitch (P4)×√2 or larger.

As the stamping nozzle 42 illustrated in FIGS. 25A and 25B has the four flow paths 51f arranged on the line connecting the center of the dug portion 50 and the center of the one side of the dug portion 50 and the four flow paths 51h arranged on the diagonal lines connecting the corner portions of the dug portion 50 to each other even when the external dimensions of the chip 1 is large, the Ag paste 7 can be more stably filled in the dug portion 50 than the stamping nozzle 42 illustrated in FIGS. 23A and 23B.

Note that, while the planar shape of the flow paths 51 has been circular in the examples illustrated in FIGS. 17A to 25B, it may be rectangular. In any example, it is preferable to have the opening diameter of the flow paths 51 to a level that does not allow the Ag paste 7 to drop during standby and also does not allow clogging by the Ag filler 11 and the spacer bead 12 to occur. Further, the number of the flow paths 51 is not limited to those of the examples illustrated in FIGS. 17A to 25B. Moreover, it is desirable to have the specifications of the planar dimensions and the depth (D) of the dug portion 50, the thickness (t) from the sidewall of the dug portion 50 to the stamping nozzle 42 and so forth identical to those of the stamping nozzle 42 illustrated in FIGS. 16A and 16B.

To apply the Ag paste 7 on the die pad 3D of the lead frame LF using the stamping nozzle 42 illustrated in FIGS. 16A and 16B, the Ag paste 7 filled in the syringe 41 of the paste applying apparatus 40 is sent to the dug portion 50 of the stamping nozzle 42 and the lower surface of the stamping nozzle 42 is abutted to the upper surface of the die pad 3D. In this manner, the Ag paste 7 filled in the dug portion 50 is detached from the dug portion 50 and transferred onto the die pad 3D. That is, on the die pad 3D, the Ag paste 7 of an amount corresponding to the volume of the dug portion 50 is transferred onto the die pad 3D. Also, a shape of the Ag paste 7 transferred on the die pad 3D is substantially the same as the shape of the dug portion 50.

As described above, since the depth (D) of the dug portion 50 is smaller than the thickness of the chip 1, the thickness of the Ag paste 7 applied on the die pad 3D is smaller (thinner) than the thickness of the chip 1. Also, since the planar dimensions of the dug portion 50 are smaller than the external dimensions of the chip 1, the external dimensions of the Ag paste 7 are smaller than the external dimensions of the chip 1.

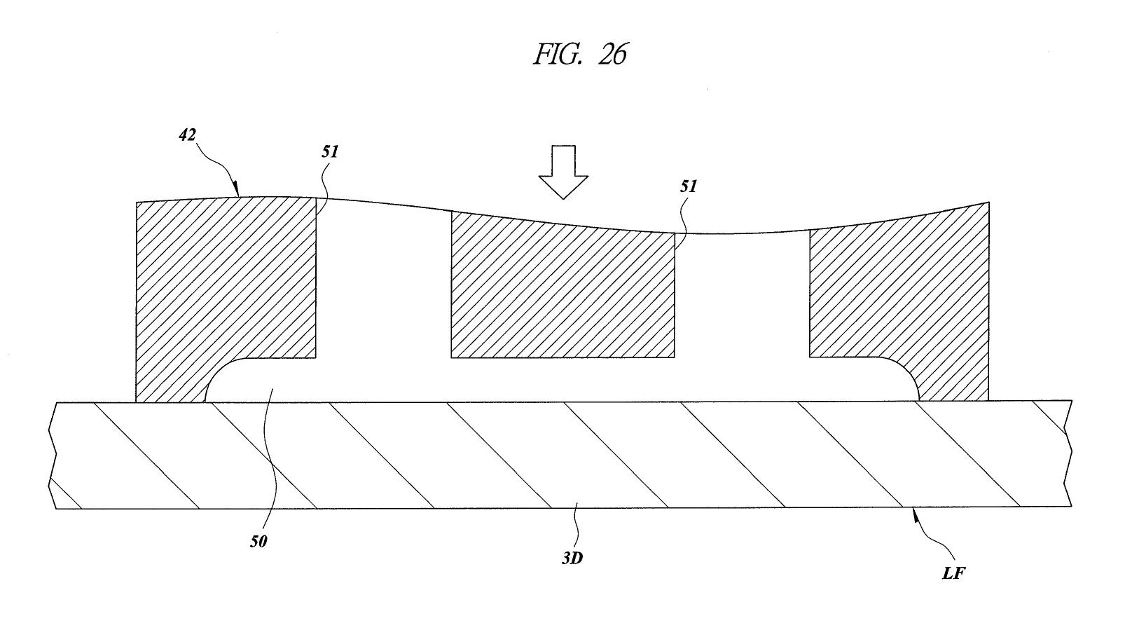

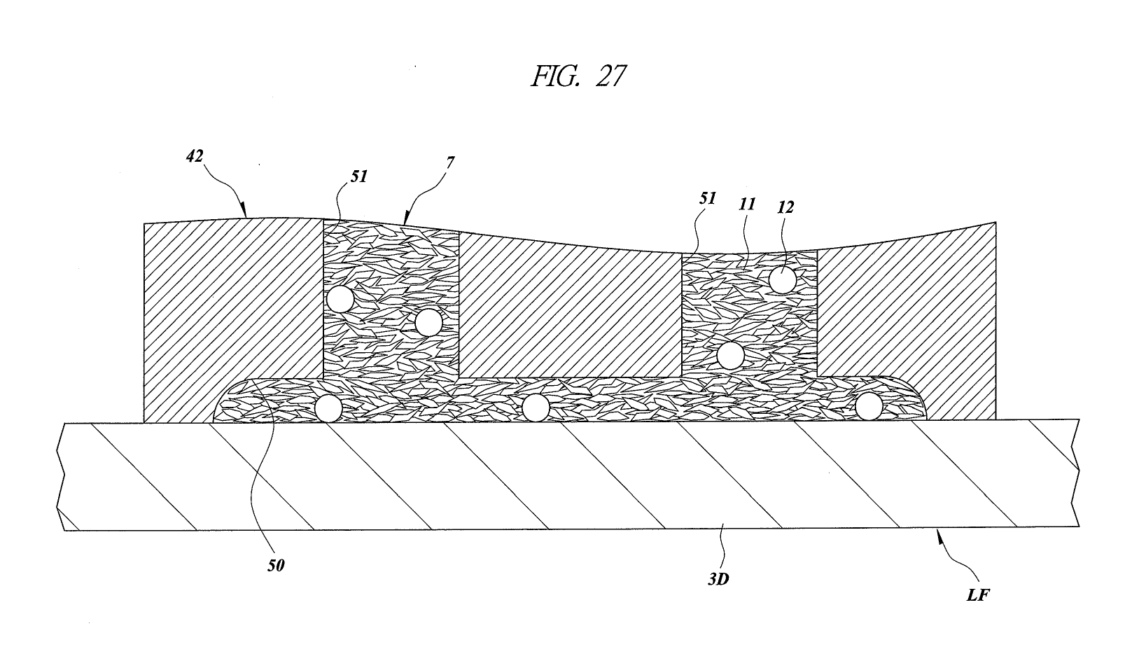

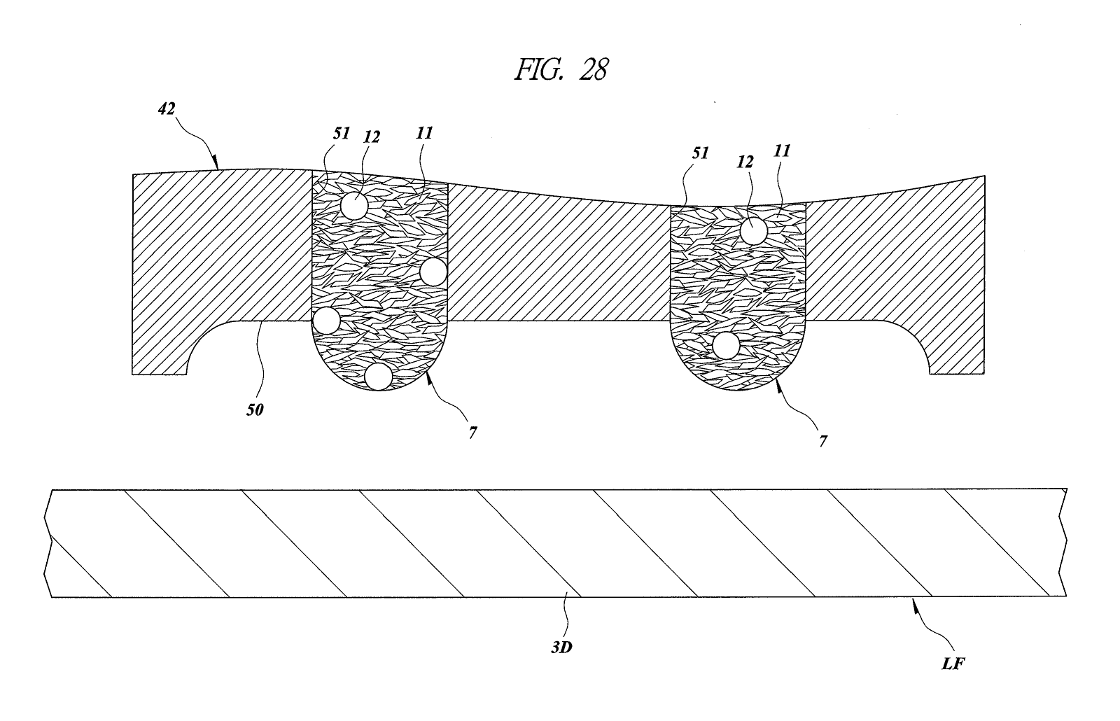

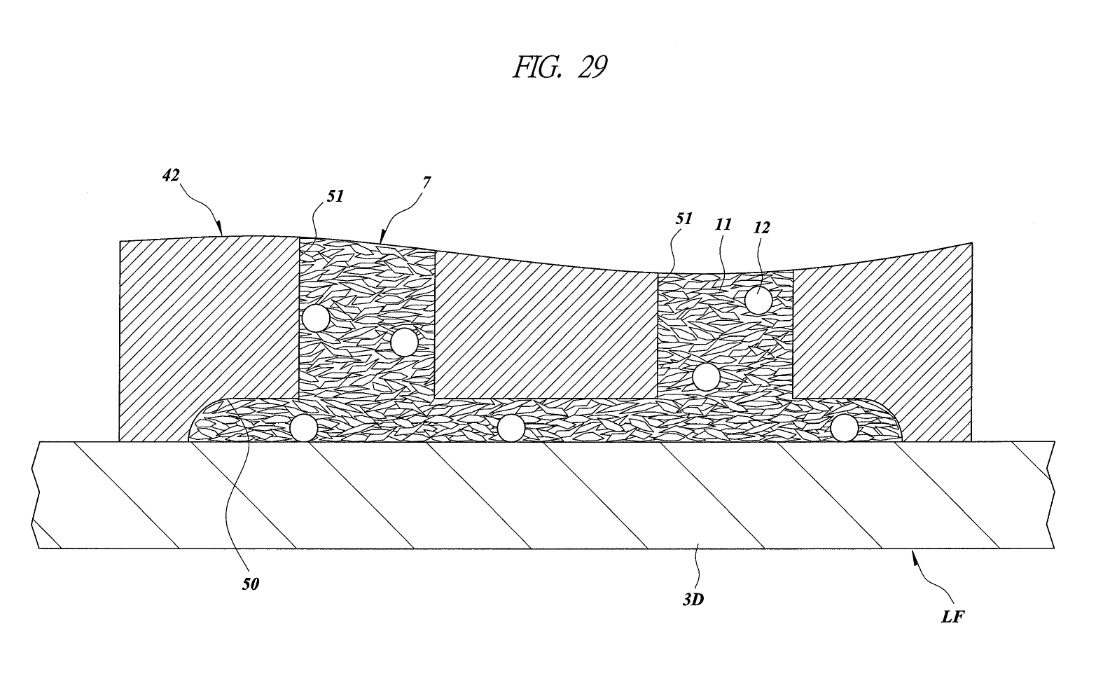

When applying the Ag paste 7 onto the die pad 3D of the lead frame LF, first, as illustrated in FIG. 26, after abutting the lower surface of the stamping nozzle 42 to the upper surface of the die pad 3D, as illustrated in FIG. 27, the Ag paste 7 is discharged to the inside of the dug portion 50 through the flow path 51 (first method). Alternatively, first, as illustrated in FIG. 28, after discharging the Ag paste 7 to the inside of the dug portion 50 through the flow path 51, as illustrated in FIG. 29, the lower surface of the stamping nozzle 42 is abutted to the upper surface of the die pad 3D (second method).

In the two methods described above, the air in the dug portion 50 is easier to be discharged in the second method than the first method. That is, in the second method, as illustrated in FIG. 28, a lower edge of the Ag paste 7 discharged to the inside of the dug portion 50 from the flow path 51 is more protruded downward than the lower surface of the stamping nozzle 42, thereby filling the Ag paste 7 inside the dug portion 50 without space while the air inside the dug portion 50 is being discharged (pushed out). As a result, voids in the Ag paste 7 applied on the die pad 3D can be reduced.

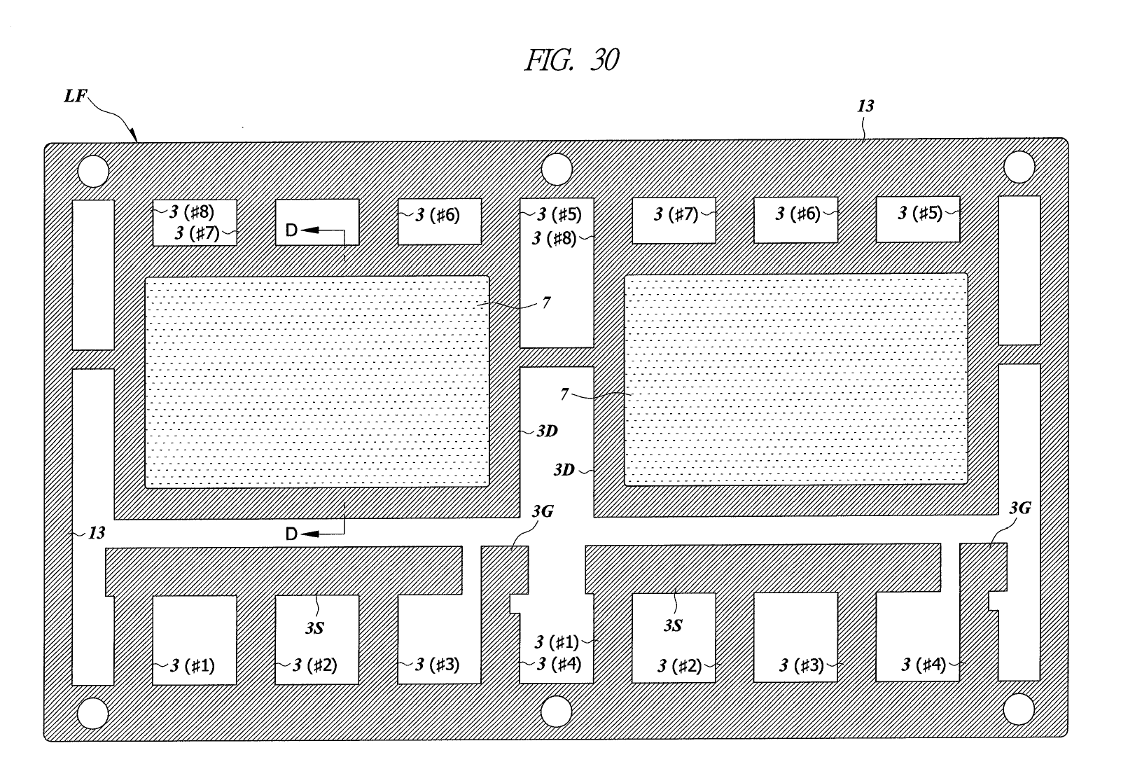

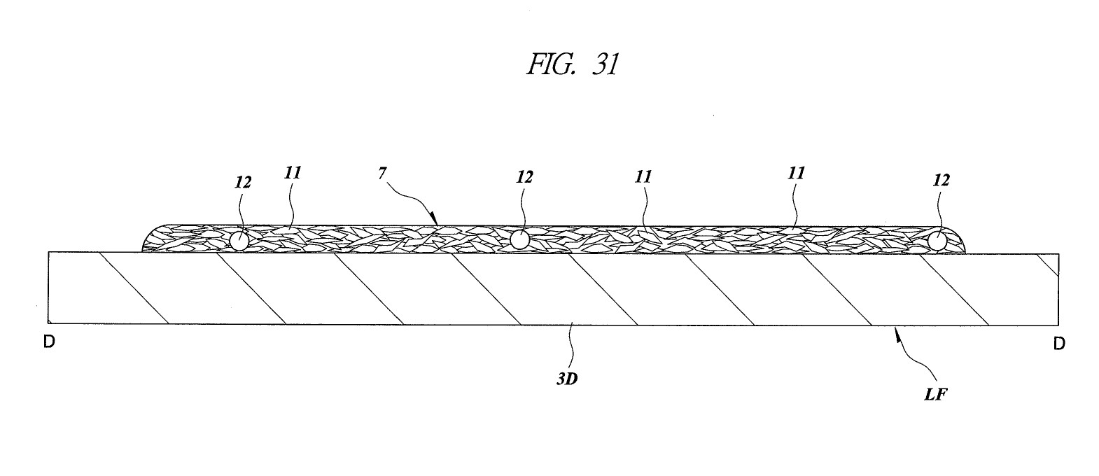

FIG. 30 is a planar view of the lead frame LF having the Ag paste 7 applied on the die pad 3D by the method described above, and FIG. 31 is a cross-sectional view along the line D-D in FIG. 30.

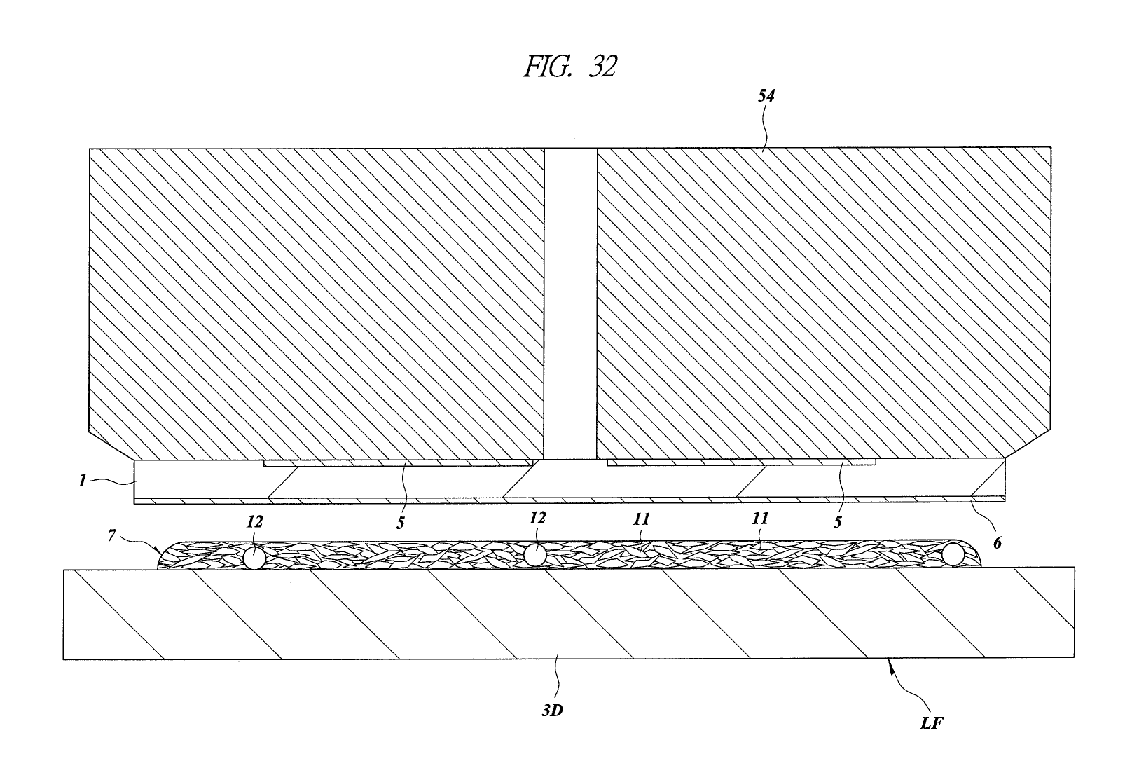

Next, as illustrated in FIG. 32, the main surface of the chip 1 is transported to above the die pad 3D while the main surface of the chip 1 is sucked and held by the die-bonding collet 54 and positioning is made so that the main surface of the chip 1 and the upper surface of the die pad 3D are in parallel.

External dimensions of the die-bonding collet 54 are preferable to be larger than the external dimensions of the chip 1. When using the die-bonding collet 54 larger than the external dimensions of the chip 1, the whole of the periphery portion of the main surface of the chip 1 is brought into contact with a lower surface of the die-bonding collet 54. In this manner, since the peripheral portion of the chip 1 will not warp when load is applied by pressing the back surface of the chip 1 to the Ag paste 7 in the next step, the whole of the back surface of the chip 1 can be wet with the Ag paste 7.

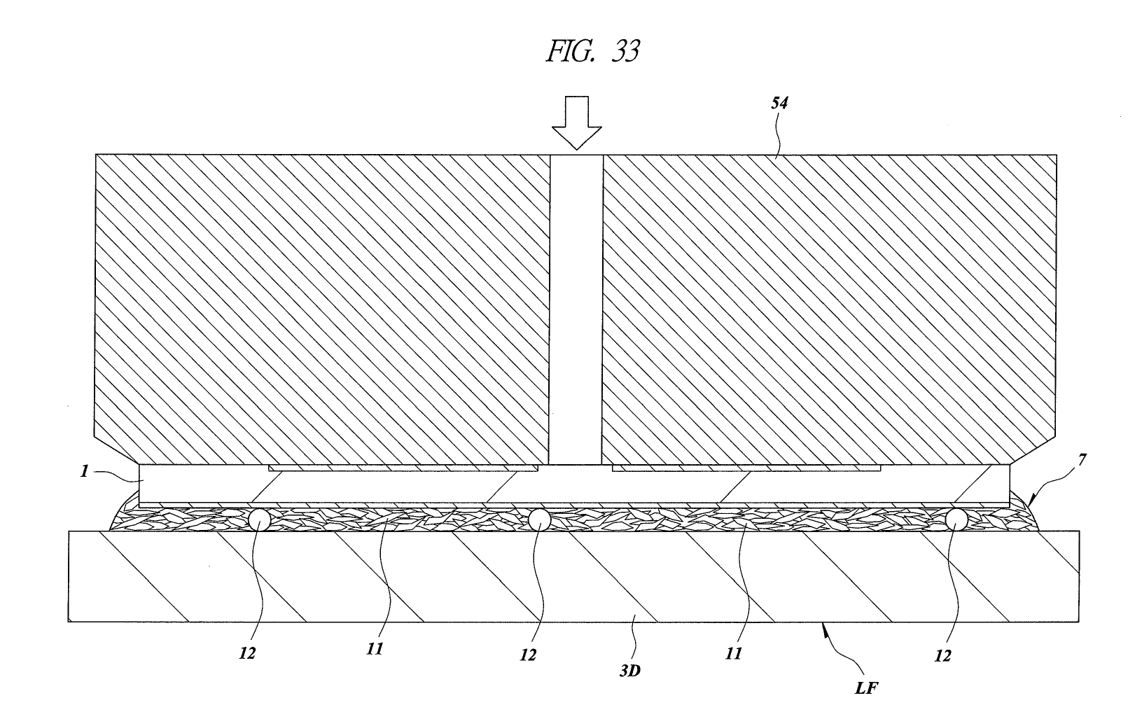

Next, as illustrated in FIG. 33, the die-bonding collet is vertically lowered to lightly press the back surface of the chip 1 to the Ag paste 7 on the die pad 3D. At this time, load applied to the Ag paste 7 (mounting load) is, for example, about 60 to 150 g/chip. As described above, since the spacer bead 12 in a spherical shape of a low-elasticity resin is contained in the Ag paste 7, when the chip 1 is pressed to the Ag paste 7, the Ag paste 7 is wet and spread in a lateral direction and, as a thickness of the Ag paste 7 is thinned to a level substantially the same as the diameter of the spacer bead 12, a part of the Ag paste 7 is leaked to the outside of the chip 1.

Here, the Ag paste 7 is applied on the die pad 3D to have its thickness being smaller than that of the chip 1 and the external dimensions being smaller than those of the chip 1, and thus the level of leakage of the Ag paste 7 to the outside of the chip 1 is small and it will not be attached to the die-bonding collet 54. Also, the Ag paste 7 will not crawl up onto the main surface (upper surface) of the chip 1 after releasing the die-bonding collet 54 from the chip 1.

Also, as illustrated in FIG. 7, a top end of a fillet of the

Ag paste 7 formed around the chip 1 is positioned between the main surface (upper surface) and the back surface (lower surface) of the chip 1. In other words, the top end of the filet of the Ag paste 7 is positioned between the main surface (upper surface) of the chip 1 and the metal film formed to the back surface (lower surface) of the chip 1 described above. That it, in other words, it is important to set the volume of the dug portion 50 of the stamping nozzle 42 (that is, the volume of the Ag paste 7 applied on the die pad 3D) so that the position of the top end of the fillet of the Ag paste 7 is at the position described above.

In this manner, a problem of short-circuiting between the drain electrode 6 formed to the back surface of the chip 1 and the gate pad 4 or the source pad 5 formed to the main surface of the chip 1 via the Ag paste 7 can be prevented. Also, it is possible to prevent a problem of short-circuiting between the drain electrode 6 and the gate extraction electrode 10 via the Ag paste 7 occurring when the Ag filler 11 cuts through the surface protective film 19 covering the main surface of the chip 1 and is brought into contact with the gate extraction electrode 10.

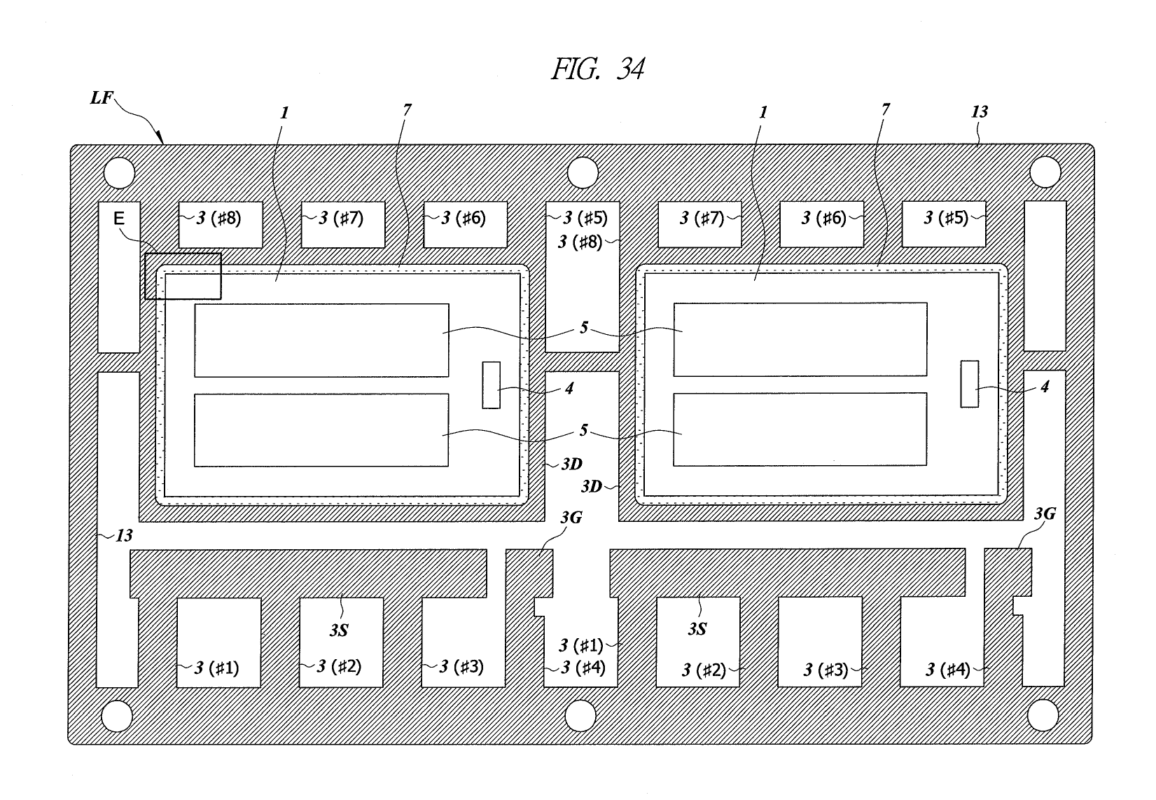

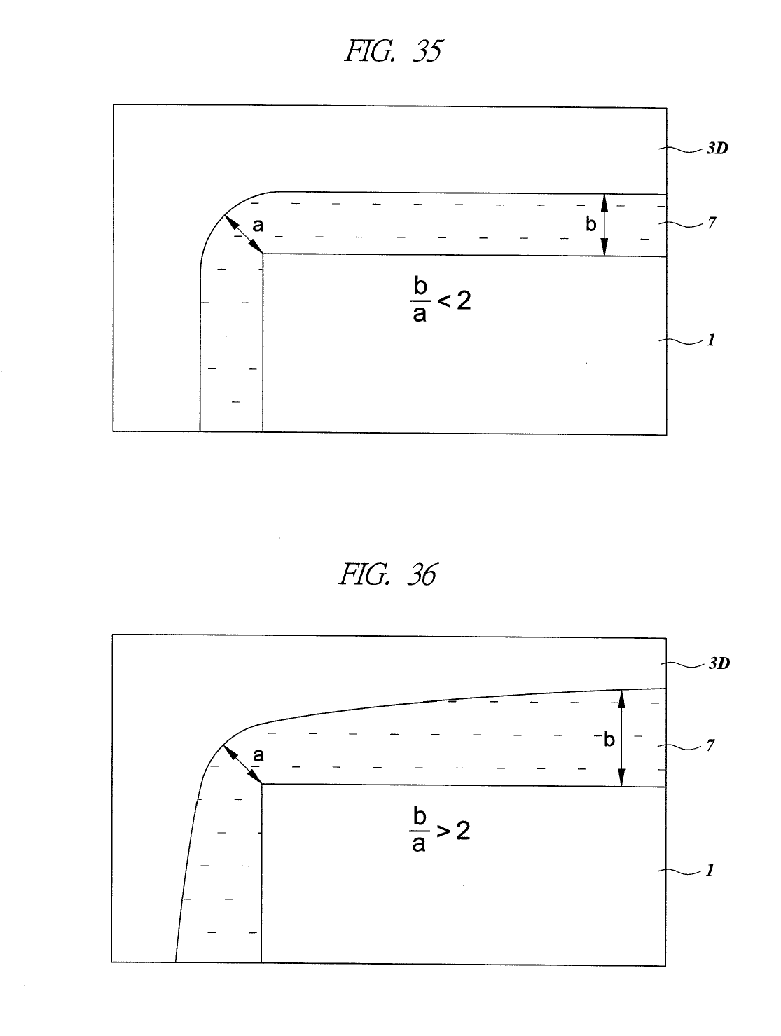

FIG. 34 is a planar view of the lead frame LG immediately after releasing the die-bonding collet 54 from the chip 1 after pressing the back surface of the chip to the Ag paste 7 using the die-bonding collet 54, and FIG. 35 is a planar view illustrating a part of FIG. 34 (the rectangular region denoted by the reference symbol E).

As illustrated in FIG. 35, when the back surface of the chip 1 is pressed to the Ag paste 7 applied on the die pad 3D, a relationship of a leaked amount (a) of the Ag paste 7 at the corner portions of the chip 1 and a leaked amount (b) of the Ag paste 7 in a region away from the corner portions is (b/a)<2. Here, the leaked amount (a) means a leaked amount to a direction tilted at 45° from the corner portion of the chip 1 and the leaked amount (b) means a leaked amount to a direction from one side of the chip 1 to a direction orthogonal to the side. Accordingly, when the Ag paste 7 is applied onto the die pad 3D in the above-described method, the leaked amount (b) in the region away from the corner portions of the chip 1 is less than twice the leaked amount (a) at the corner portions of the chip 1 at most. Thus, even when the thickness of the chip 1 is 100 μm or smaller than, a part of the Ag paste 7 leaked to the outside of the chip 1 will not crawl up to the upper surface (main surface) of the chip 1.

In contrast, FIG. 36 illustrates a leaked amount of the Ag paste 7 when the back surface of the chip 1 is pressed to the Ag paste 7 after applying the Ag paste 7 on the die pad 3D using an existing multi-point nozzle method. In this case, a relationship of a leaked amount (a) of the Ag paste 7 at the corner portions of the chip 1 and a leaked amount (b) of the Ag paste 7 in a region away from the corner portions of the chip 1 is (b/a)>2. That is, the leaked amount (b) of the Ag paste 7 in the region away from the corner portions of the chip 1 is more than twice the leaked amount (a) of the Ag paste 7 at the corner portions of the chip 1. Thus, when the thickness of the chip 1 is 100 μm or smaller, a part of the Ag paste 7 leaked to the outside of the chip 1 crawls up to the upper surface (main surface) of the chip 1.

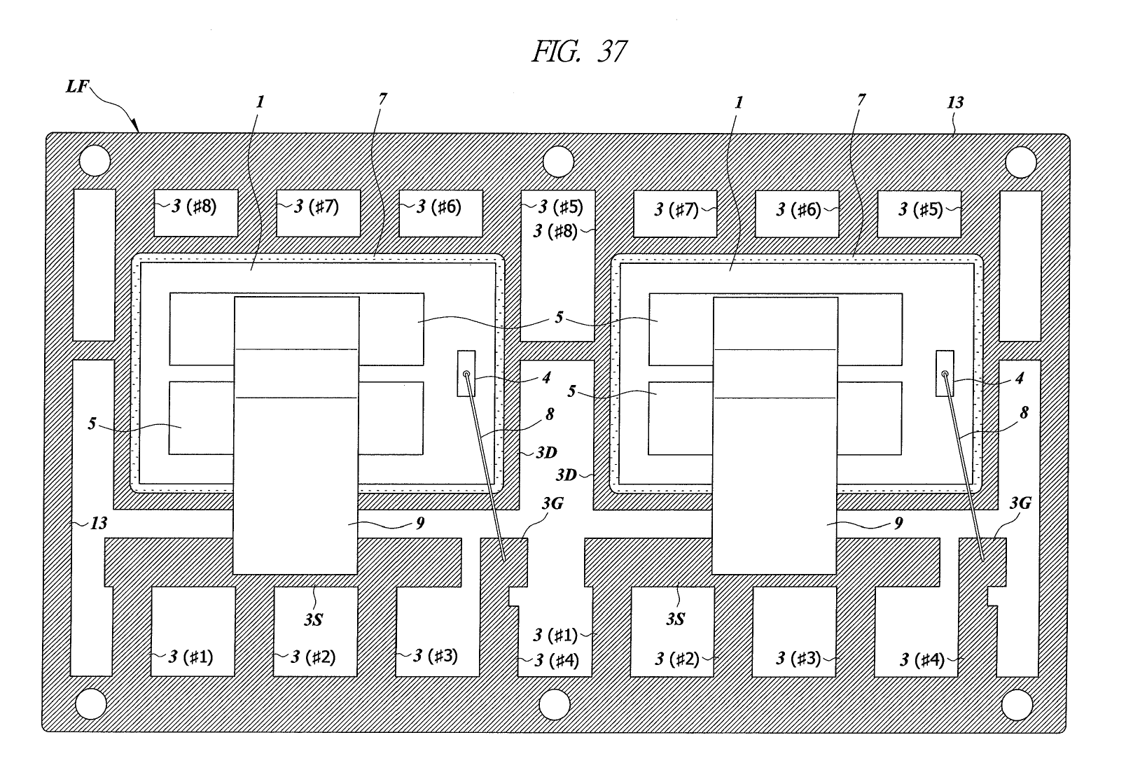

Next, after curing the Ag paste 7 by heating the lead frame LF at about 200° C. in a baking furnace, as illustrated in FIG. 37, the gate pad 4 of the chip 1 and the gate post 3G of the lead frame

LF are electrically connected by the Au wire 8 and the source pad 5 of the chip 1 and the source post 3S of the lead frame LF are electrically connected by the Al ribbon 9. A ball bonding method using both heat and ultrasonic vibration is used in the bonding of the Au wire 8 and wedge bonding method using ultrasonic vibration is used in the bonding of the Al ribbon 9.

The order of bondings of the Au wire 8 and the Al ribbon 9 described above is optional. However, since the width and thickness of the Al ribbon 9 are larger than the diameter of the Au wire 8, vibration energy applied to the chip 1 upon bonding of the Al ribbon 9 is larger than vibration energy applied to the chip 1 upon bonding of the Au wire 8. Thus, when the bonding of the Al ribbon 9 is performed after the bonding of the Au wire 8, the connection strength of the Au wire 8 and the gate pad 4 is lowered by the vibration energy of upon bonding the Al ribbon 9, and in some cases, there is a possibility of exfoliation of the Au wire 8 from the gate pad 4. In addition, when the wedge tool used in the bonding of the Al ribbon 9 comes into contact with the Au wire 8, there is a possibility of damage or cutting of the Au wire 8. Thus, it is desirable to perform the bonding of the Al ribbon 9 first and then perform the bonding of the Au wire 8.

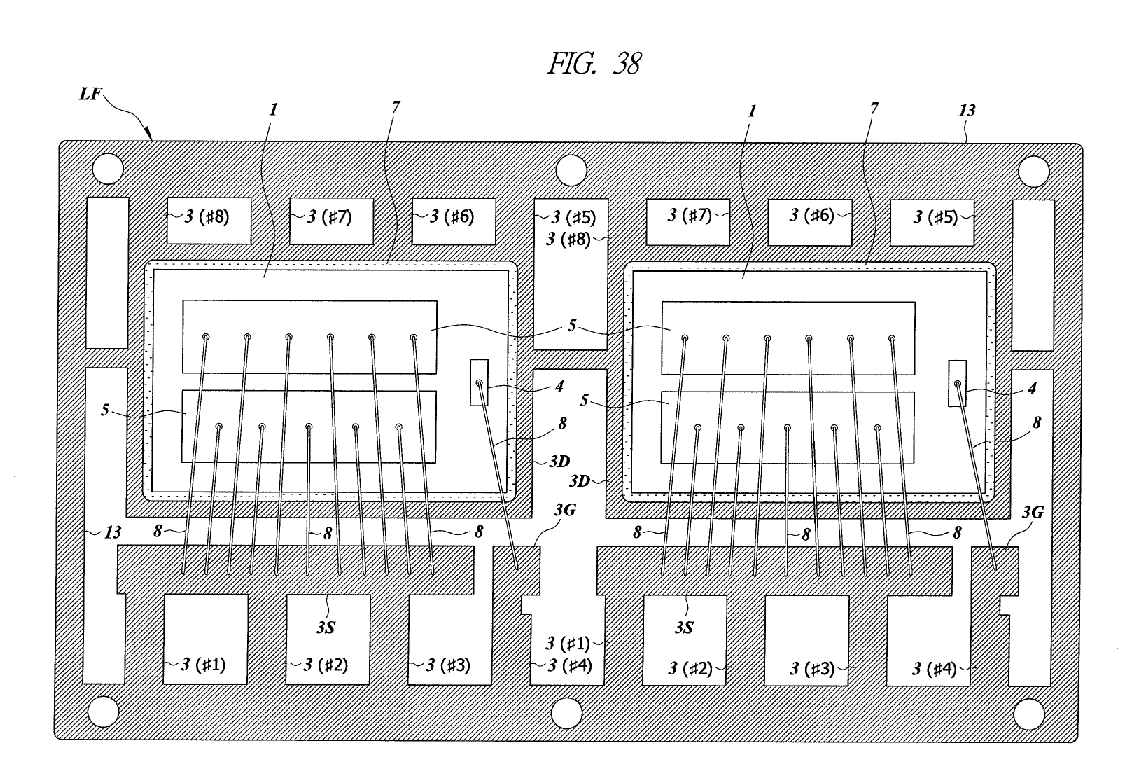

A conductive material for connecting the source pad 5 and the source post 3S is not limited to the Al ribbon 9; for example, as illustrated in FIG. 38, the source pad 5 and the source post 3S may be connected by using a plurality of Au wires 8. Here, by alternately arranging and connecting long ones of the Au wires 8 and short ones of the Au wires 8 (to make a houndstooth array), the source pad 5 and the source post 3S can be efficiently connected by the plurality of Au wires 8. Also, a metal clip which is a conductive material similar to the Al ribbon 9 may be used. Here, “clip” means a thin metal plate of a Cu alloy or Al previously shaped into a predetermined loop shape and by a predetermined length and one end of the clip is put on the source pad 5 and the other end is put on the source post 3S so that the one end of the clip and the source pad 5 are connected at the same time as the other end of the clip and the source post 3S are connected. There are solder joining, Ag paste joining, ultrasonic joining, and so forth as method of the connection.

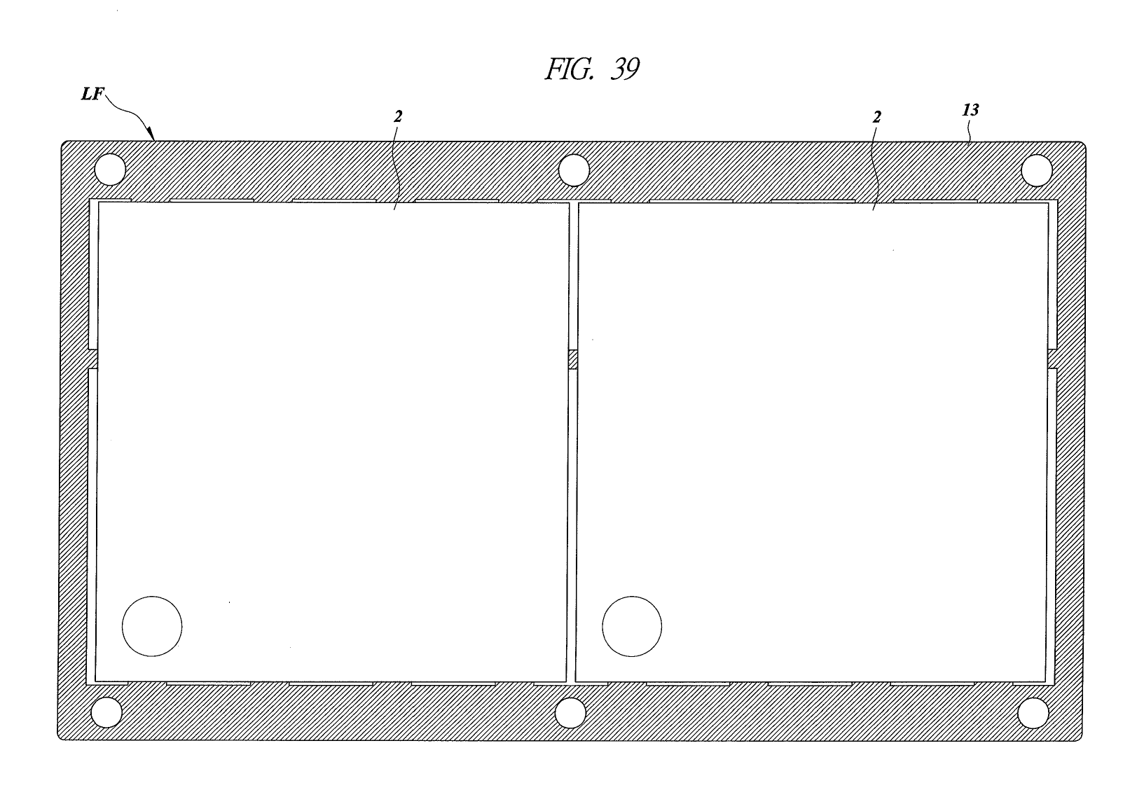

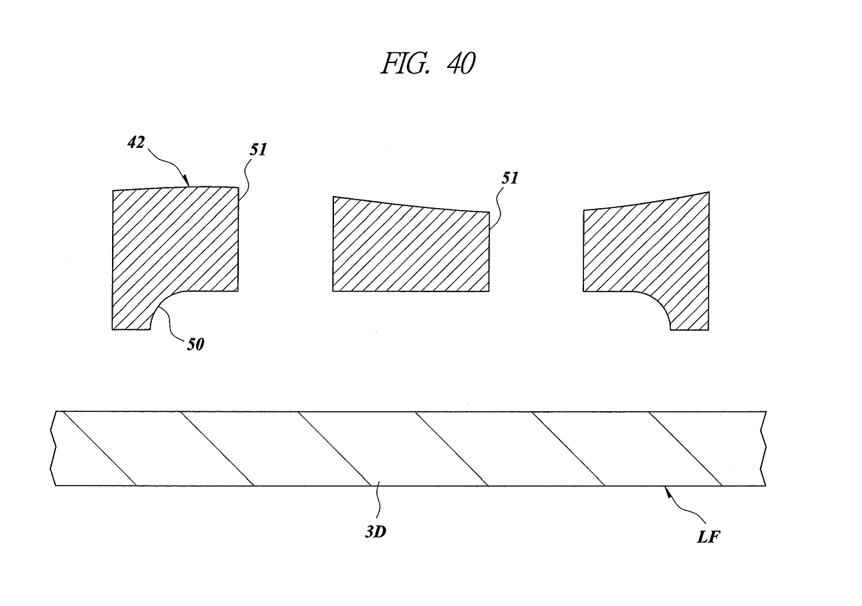

Next, as illustrated in FIG. 39, the chip 1 is sealed with the mold resin 2. Thereafter, the frame 13 of the lead frame LF exposed to the outside of the mold resin 2 is cut and removed, thereby finishing the semiconductor device (small surface-mount package) of the present embodiment illustrated in FIGS. 1 to 5.

In this manner, according to the method of manufacturing of the present embodiment described above, when mounting the thin chip 1 having a thickness of 100 μm or smaller on the die pad 3D of the lead frame LF, the problem of crawling up of the Ag paste 7 to the upper surface of the thin chip 1 can be improved. Accordingly, thinning of the chip 1 to be mounted on the die pad 3D can be advanced and thus thinning and performance improvement (lowering of ON resistance of power MOSFET) of the small surface-mount package in which the chip 1 to which a power MOSFET is formed can be advanced.

While using the Ag paste 7 as a die-bonding material for connecting the die pad 3D of the lead frame LF and the chip 1 has been described in the present embodiment, the method of applying the die-bonding material using the stamping nozzle 42 described above can be used in using a solder paste as the die-bonding material.

The solder paste is a conductive die-bonding material in which flux, in which rosin is a main component, and microparticles of solder are kneaded and mixed; as solder components, in addition to a Sn (tin) —Pb (lead) alloy, there are a Sn—Ag—Cu alloy not containing Pb, a Sn—Zn (zinc) —Bi (bismuth) alloy, a Sn—Ag—In (indium) —Bi alloy, etc. Since solder pastes have heat resistance although their conductivity is lower than the Ag paste 7, they are suitable die-bonding materials to be used in semiconductor devices used in high-temperature environment such as a semiconductor package for sealing the chip 1 in which a power MOSFET for automobile use is formed.

To apply a solder paste onto the die pad 3D of the lead frame LF, first, as illustrated in FIG. 40, the position of the stamping nozzle 42 is determined above the die pad 3D. Although illustration is omitted, the stamping nozzle 42 is attached to the tip of the syringe 41 of the paste applying apparatus 40 (see FIG. 15) described above and the solder paste is filed inside the syringe 41.

Although the number and layout of the flow paths 51 provided to the stamping nozzle 42 are suitably optimized in accordance with the external dimensions of the chip 1 and a ratio of the length of the longer side and the length of the shorter side, etc., here, the stamping nozzle 42 illustrated in FIGS. 16A and 16B is used. Also, when the planar shape of the chip 1 is rectangular, the planar shape of the dug portion 50 is also rectangular and the ratio of the length of the longer side and the length of the shorter side of the dug portion 50 is substantially the same as the ratio of the length of the longer side and the length of the shorter side of the chip 1. Further, the planar dimensions and the depth of the dug portion 50 are smaller than those of the chip 1. For example, when the thickness of the chip 1 is 50 μm, the depth of the dug portion 50 is set to 30 to 40 μm.

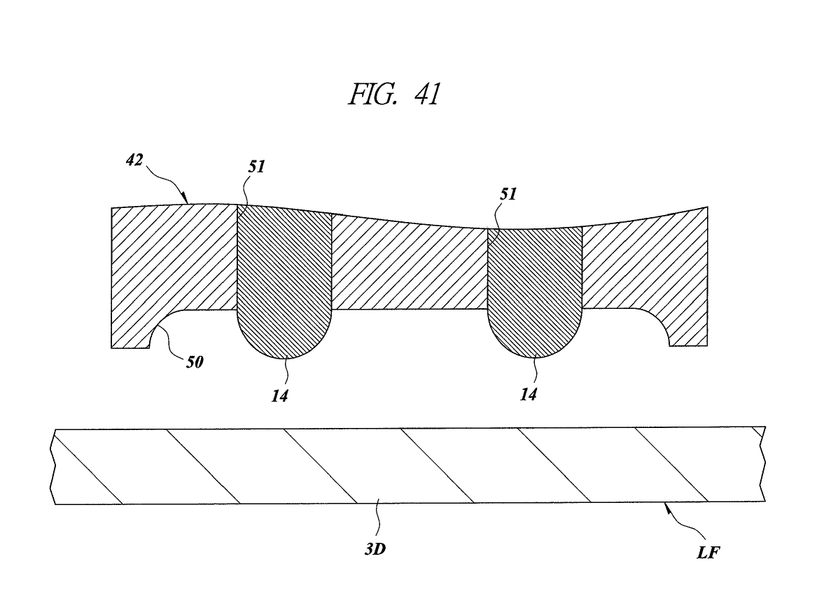

Next, as illustrated in FIG. 41, a solder paste 14 is discharged to the inside of the dug portion 50 through the flow path 51. Then, a lower end of the solder paste 14 discharged to the inside of the dug portion 50 is protruded more downward than the lower surface of the stamping nozzle 42. In this manner, when the lower surface of the stamping nozzle 42 is abutted to the upper surface of the die pad 3D in the next step, the solder paste 14 can be filled inside the dug portion 50 without space while the air inside the dug portion 50 is being discharged.

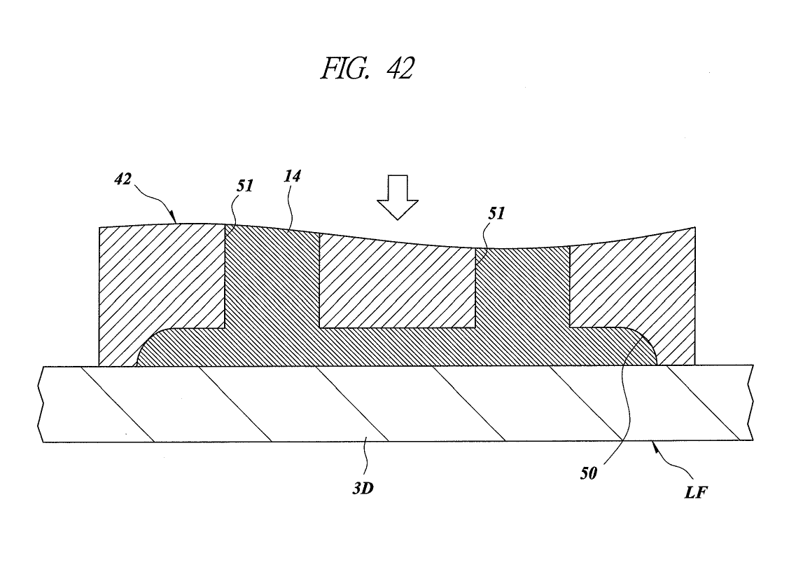

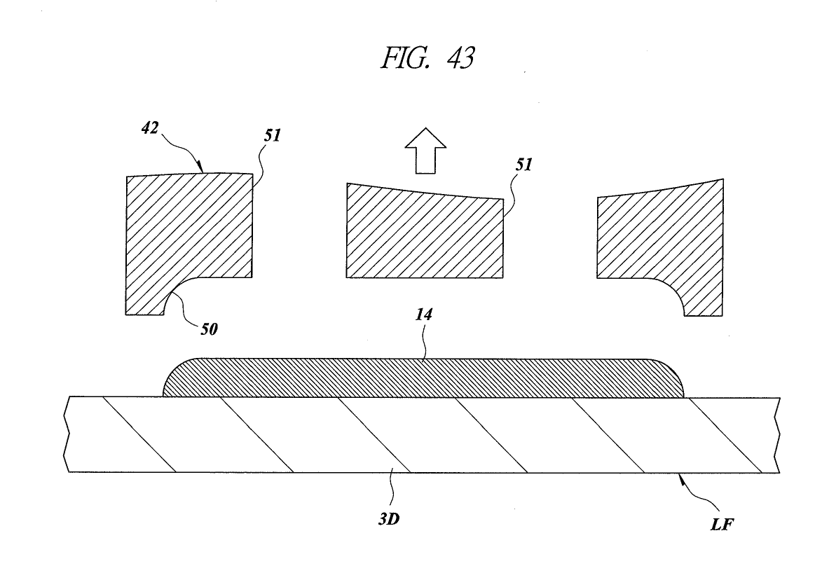

Next, as illustrated in FIG. 42, the lower surface of the stamping nozzle 42 is abutted to the upper surface of the die pad 3D and the solder paste 14 is filled inside the dug portion 50, and then, as illustrated in FIG. 43, the stamping nozzle 42 is pulled up, thereby transferring the solder paste 14 inside the dug portion 50 onto the die pad 3D. Also in this case, by finishing the inner wall of the dug portion 50 like a mirror, variations of the applied amount of the solder paste 14 transferred onto the die pad 3D can be reduced.

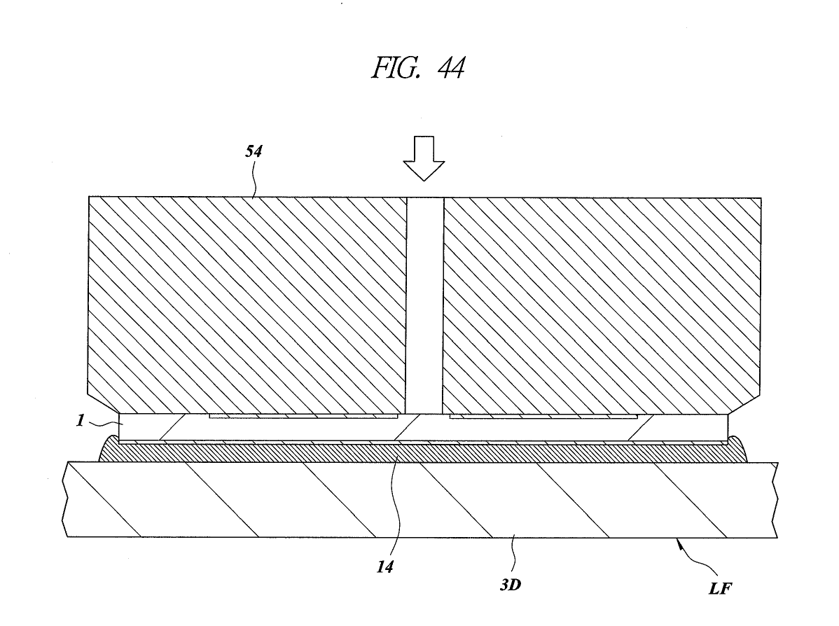

Next, as illustrated in FIG. 44, the chip 1 is transported to the above of the die pad 3D while the main surface of the chip 1 being sucked and held by the die-bonding collet 54, and the back surface of the chip 1 is lightly pressed to the solder paste 14 on the die pad 3D so that the main surface of the chip 1 and the upper surface of the die pad 3D are in parallel, thereby applying load to the solder paste 14.

In this situation, the solder paste 14 is wet and spread in the lateral direction and a part of the solder paste 14 leaks to the outside of the peripheral portion of the chip 1. However, since the solder paste 14 applied to the die pad 3D has a thickness smaller than that of the chip 1 and also external dimensions of the solder paste 14 are smaller than those of the chip 1, the solder paste 14 leaked to the outside of the chip 1 will not attach the die bonding collet 54. Moreover, the solder paste 14 will not crawl up to the main surface (upper surface) after the die-bonding collet 54 is released from the chip 1.

Further, here, the chip 1 is slightly buried inside the solder paste 14. That is, an upper surface of the solder paste 14 leaked to the outside from the peripheral portion of the chip 1 is at a position higher than the back surface of the chip 1 in the thickness direction (height direction) of the chip. In other words, the upper surface of the solder paste 14 leaked to the outside from the peripheral portion of the chip 1 is positioned between the main surface (upper surface) and the back surface (lower surface) of the chip 1. Alternatively, the upper surface of the solder paste 14 leaked to the outside from the peripheral portion of the chip 1 is positioned between the main surface (upper surface) of the chip 1 and the metal film described above formed to the back surface (lower surface) of the chip 1.

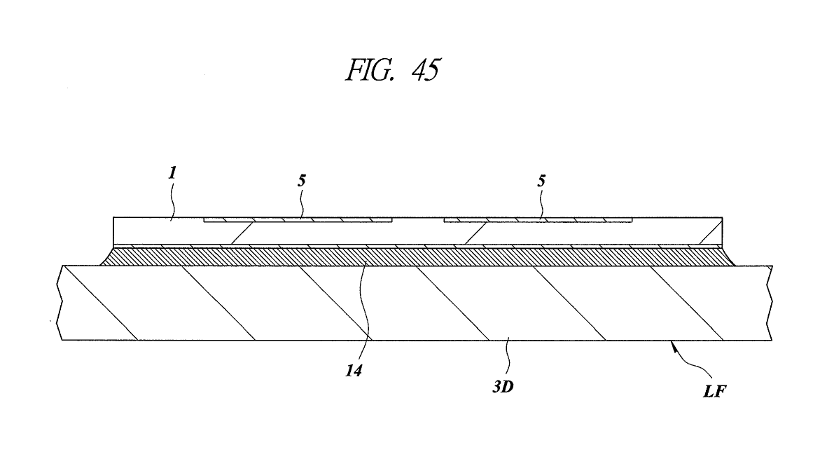

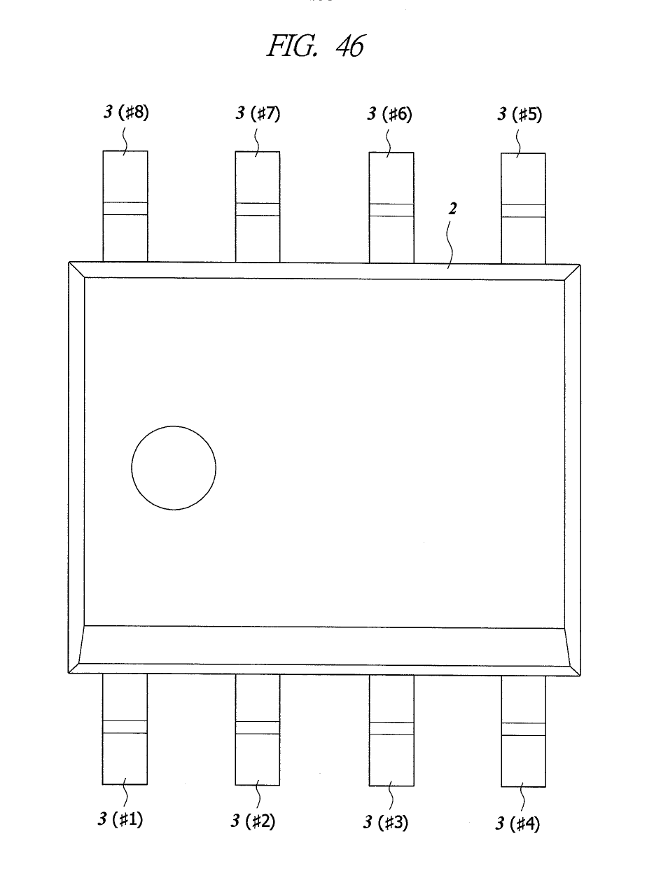

Next, after releasing the die-bonding collet 54 from the chip 1, the solder paste 14 is ref lowed in a reflow furnace, and then the surface of the lead frame LF is washed using a flux washer agent, thereby finishing mounting of the chip 1 (FIG. 45).

Here, as illustrated in FIG. 45, solder of the solder paste 14 melted and solidified is joined (metal-coupled) with the metal film of the back surface of the chip 1 and the top end of the fillet of the solidified solder does not goes beyond the metal film. This is because the chip 1 is formed of silicon and the solder of the melted solder paste 14 has a characteristic not to be wet on silicon (not to have metal coupling). Thus, as long as the solder paste 14 does not crawl up to the main surface of the chip 1 upon mounting the chip, the reliability of the joint of the chip 1 and the die pad 3D can be improved by forming the solder paste 14 applied on the die pad 3D to be thicker than the Ag paste 7 and forming thickness the solder after reflowing thick.

Note that, the following steps (bonding of the Au wire 8 and Al ribbon 9, resin sealing of the chip 1 etc.) are the same as those described above and thus the descriptions thereof are omitted.

In this manner, according to the method of manufacturing of the present embodiment, a problem of crawling up of the solder paste 14 to the upper surface of the thin chip 1 when mounting the thin chip 1 having a thickness of 100 μm or smaller on the die pad 3D of the lead frame LF can be improved. In this manner, even when the solder paste 14 is used as a die-bonding material, thinning of the chip 1 to be mounted on the die pad 3D can be advanced.

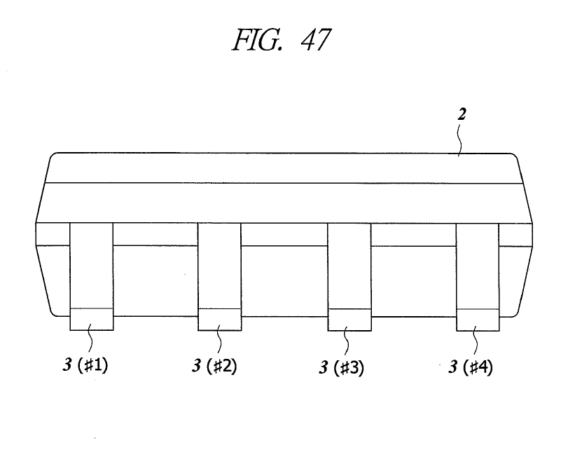

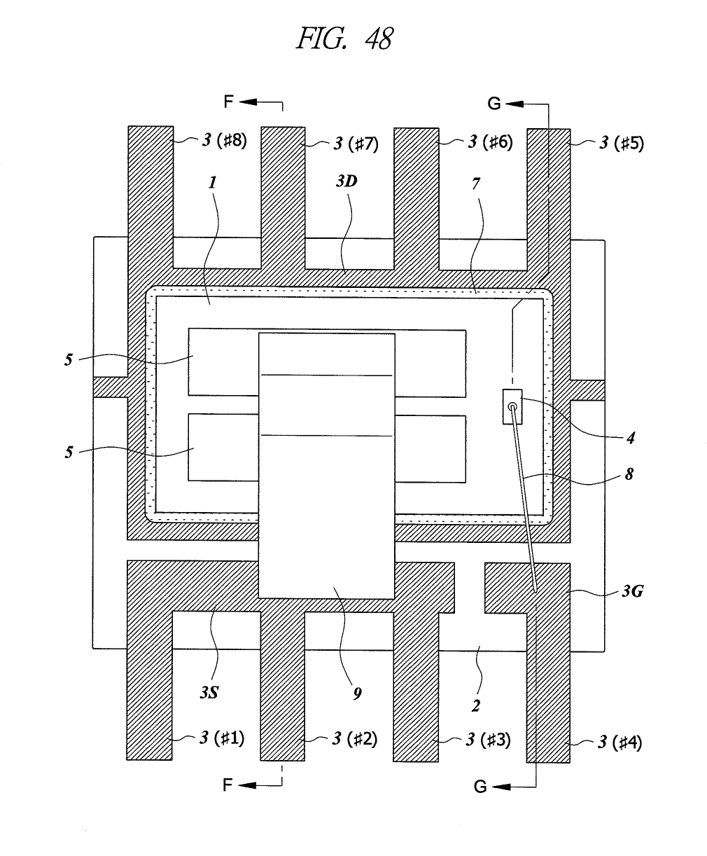

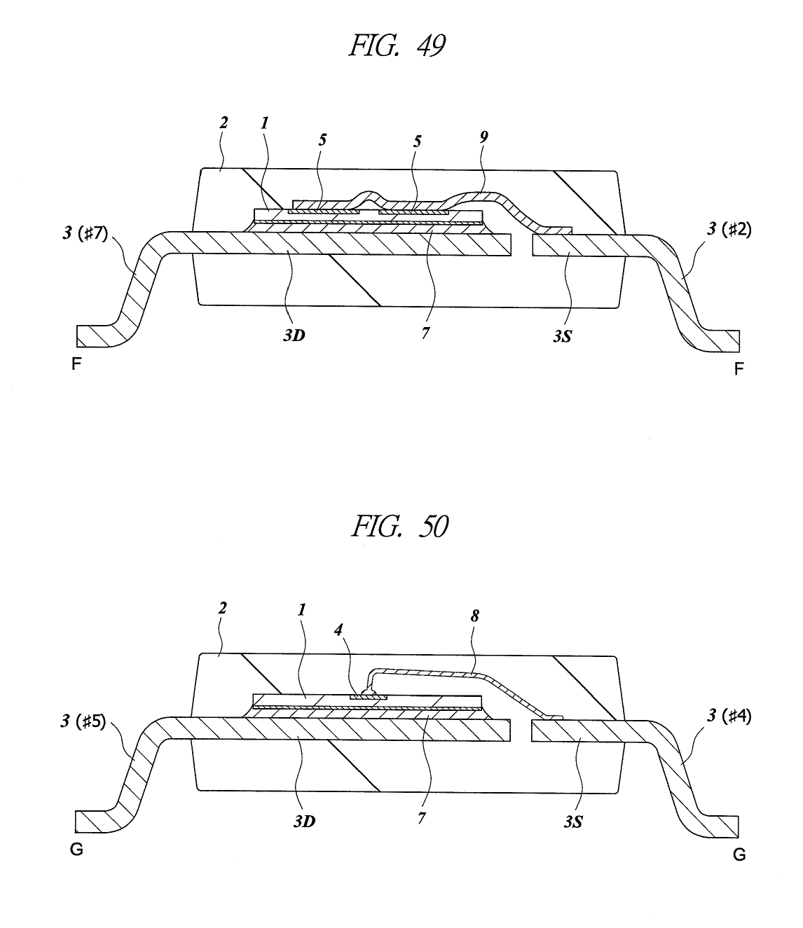

In addition, the small surface-mount package sealing the chip 1 described above is not limited to FLP mentioned above and various surface-mount packages can be adopted; for example, an SOP8 as illustrated in FIGS. 46 to 50 can be adopted. FIG. 46 is a planar view of the SOP8, FIG. 47 is a side view of the SOP8, FIG. 48 is a planar view illustrating an inner structure of the SOP8, FIG. 49 is a cross-sectional view along the line F-F in FIG. 48, and FIG. 50 is a cross-sectional view along the line G-G in FIG. 48. As illustrated in the drawings, the SOP8 is a surface-mount package in which the leads 3 (#1 to #8) protruded from two side surfaces of the mold resin 2 are shaped in a gull-wing like shape.

Also in this case, by applying the Ag paste 7 (or the solder paste 14) on the die pad 3D using the stamping nozzle 42 described above, the problem of crawling up of the Ag paste 7 (or the solder paste 14) to the upper surface of the thin chip 1 can be improved and thus thinning of the chip 1 to be mounted on the die pad 3D can be advanced.

Moreover, while mounting the chip 1 to which a power MOSFET is formed on the die pad 3D has been described in the present embodiment, the element formed to the chip 1 may be an IGBT (Insulated Gate Bipolar Transistor). The chip 1 to which an IGBT is formed has a collector electrode formed to its back surface, and thus the Ag paste 7 or the solder paste 14 is used as a die-bonding material when mounting the chip 1 onto the die pad 3D. Therefore, also in this case, by applying a die-bonding material using the stamping nozzle 42 described above, the problem of crawling up of the die-bonding material to the upper surface of the chip 1 can be improved.

### Second Embodiment

The method of applying a die-bonding material onto a die pad of a lead frame using the stamping nozzle 42 described above is applicable to manufacturing of a small surface-mount package in which a plurality of chips are mounted on a die pad.

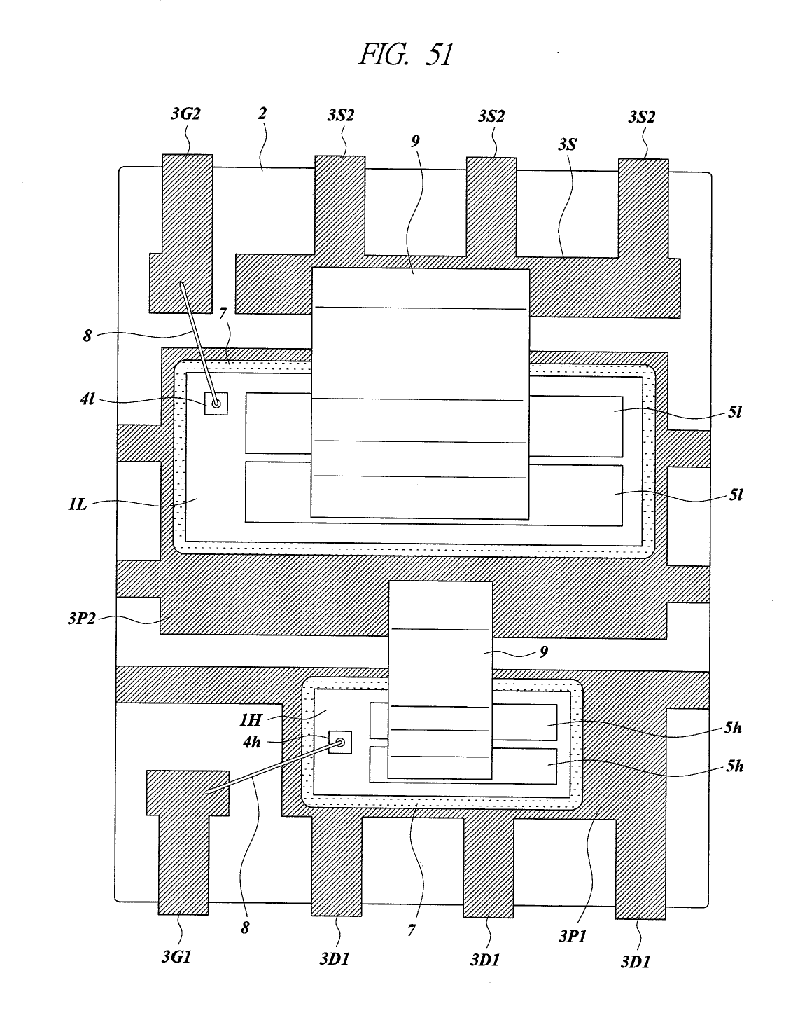

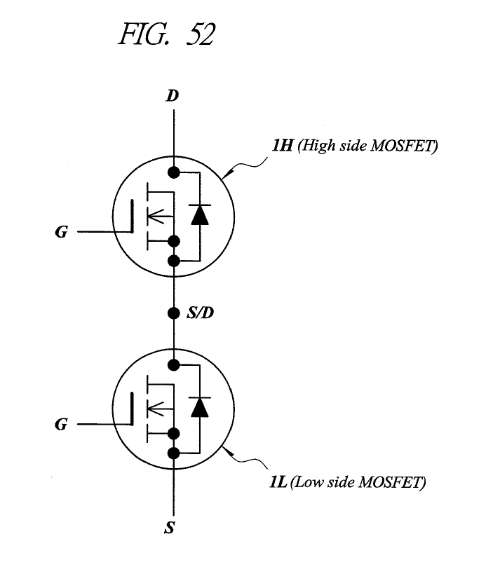

FIG. 51 is a planar view illustrating an inner structure of a semiconductor device of the present embodiment, and FIG. 52 is an inner equivalent circuit diagram of the semiconductor device. The semiconductor device of the present embodiment is a small surface-mount package in which two chips 1H and 1L are sealed with a mold resin 2. Various shapes such as FLP, SOP8 described above and so forth can be adopted as a shape of the package.

To a main surface of the chip 1H having a smaller diameter size of the two chips 1H and 1L, a high-side MOSFET is formed; and, to a main surface of the chip 1L having a larger diameter size, a low-side MOSFET is formed. Thicknesses of the two chips 114 and 1L are both, for example, 100 lam or smaller. A source of the high-side MOSFET and a drain of the low-side MOSFET are electrically connected, thereby forming, for example, a DC-DC converter. Specific structures of the high-side MOSFET and the low-side MOSFET are substantially the same as that of the power MOSFET and thus illustrations of them will be omitted.

The chip 1H having a smaller diameter size of the two chips 1H and 1L is mounted on a die pad 3P1 that is integrally formed with three drain leads 3D1, having a main surface of the chip 1H facing upward. To the main surface of the chip 1H, one gate pad 4h and two source pads 5h having a larger area than the gate pad 4h are formed. A back surface of the chip 1H forms a drain of the high-side MOSFET and joined to an upper surface of the die pad 3P1 via the Ag paste 7 same as that used in the first embodiment.

On the contrary, the chip 1L having a larger external dimensions is mounted on a die pad 3P2 having a larger area than the die pad 3P1, having a main surface of the chip 1L facing upwards. To the main surface of the chip 1L, one gate pad 41 and two source pads 51 having a larger area than the gate pad 41 are formed. A back surface of the chip 1L forms a drain of the low-side MOSFET and joined to an upper surface of the die pad 3P2 via the Ag paste 7 same as that used in the first embodiment.

To one side line of the mold resin 2, one gate lead 3G1 is arranged together with the three drain leads 3D1. In addition, the gate pad 4h of the chip 1H and the gate lead 3G1 are electrically connected via the Au wire 8 and the source pad 5h of the chip 1H and the die pad 3P2 are electrically connected via the Al ribbon 9.

Also, to another side line of the mold resin 2, three source leads 3S2 and one gate lead 3G2 are arranged. The three source leads 3S2 are mutually coupled inside of the mold resin 2 and the coupled part (source post 3S) and the source pad 51 of the chip 1L are electrically connected via the Al ribbon 9. Moreover, the gate lead 3G2 is electrically connected to the gate pad 41 of the chip 1L via the Au wire 8.

Also in the semiconductor device of the present embodiment configured in the above-described manner, the Ag paste 7 is applied to each of the upper surfaces of the two die pads 3P1 and 3P2 using the stamping nozzle 42 described above. In this manner, a problem of crawling up of the Ag paste 7 to the upper surfaces of the thin chips 1H and 1L can be improved, thereby advancing thinning of the chips 1H and 1L.

Note that, as the external dimensions of the two chips 1H and 1L are different, the stamping nozzle 42 for applying the Ag paste 7 on the die pad 3P1 and the stamping nozzle 42 for applying the Ag paste 7 on the die pad 3P2 to be used are different in planar size of the dug portion 50. Also, instead of the Ag paste 7, the solder paste 14 can be used.

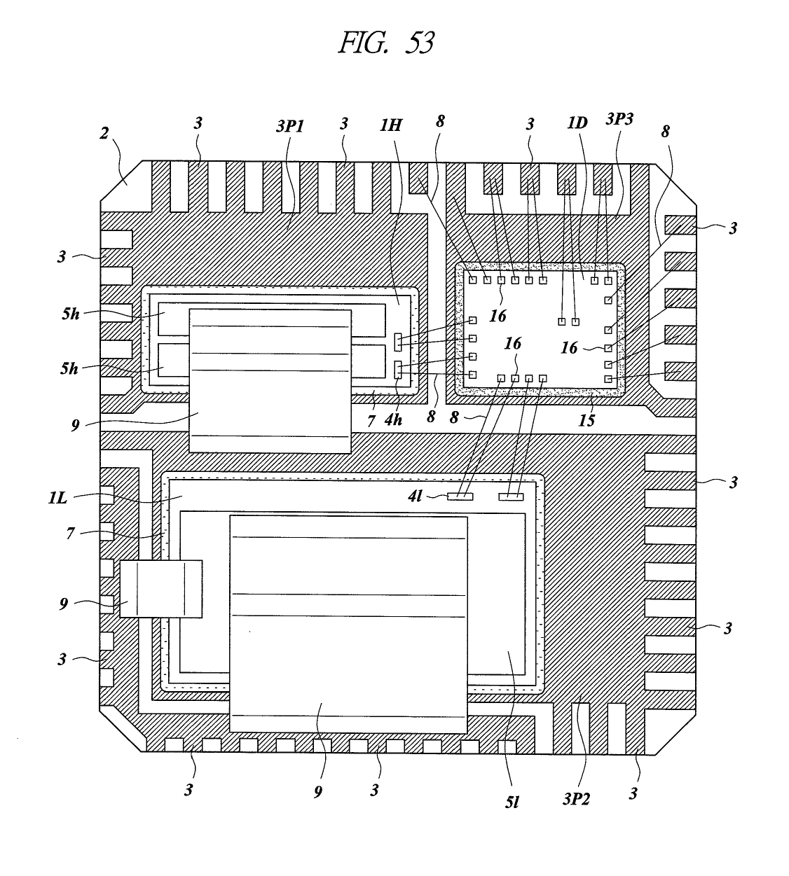

FIG. 53 is a planar view illustrating an inner structure of a system in package (SIP) in which the two chips 1H and 1L and a third chip 1D to which a driver IC (or a control IC) is formed are sealed with the mold resin 2.

The chip 1H to which the high-side MOSFET is joined to the upper surface of the die pad 3P1 via the Ag paste 7 and the chip 1L to which the low-side MOSFET is formed is joined to the upper surface of the die pad 3P2 via the Ag paste 7. Thicknesses of the two chips 1H and 1L are both 100 μm or smaller. Thus, also when mounting the chips 1H and 1L to the die pads 3P1 and 3P2, by applying the Ag paste 7 onto the die pads 3P1 and 3P2 by the stamping method using the stamping nozzle 42 described above, the problem of crawling up of the Ag paste 7 to the upper surfaces of the chips 1H and 1L can be improved.

On the contrary, the chip 1D to which a driver IC is formed is joined to an upper surface of a die pad 3P3 via an insulating paste 15. The insulating paste 15 is an insulating die-bonding material in which silica is diffused in a thermo-setting resin such as epoxy resin.

In a peripheral portion of a main surface of the chip 1D, a plurality of electrode pads (bonding pads) 16 electrically connected to elements forming the driver IC are formed. These electrode pads 16 are electrically connected to the gate pads 4h and 41 of the chips 1H and 1L or the leads 3 via the Au wire 8. In this manner, the chip 1D to which the driver IC is formed is not required to have an electrical conduction between its back surface and the die pad 3P3, and thus the chip 1D is mounted on the die pad 3P3 via the insulating paste 15 which is an insulating die-bonding material.

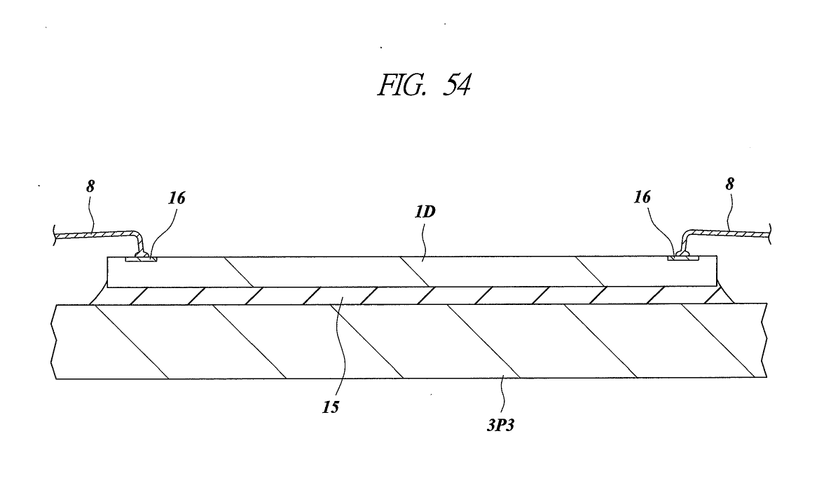

FIG. 54 is an enlarged cross-sectional view of the die pad 3P3 and the chip 1D mounted on the upper surface of the die pad 3P3. To mount the chip 11) onto the die pad 3P3, first the insulating paste 15 is applied onto the die pad 3P3 and secondly the chip in is pressed from above onto the insulating paste 15, and then the whole of the back surface of the chip 1D is wetted by the insulating 15 followed by thermally curing the insulating paste 15.

Also in this case, when the thickness of the chip 1D is smaller than or equal to 100 μm, the phenomenon, i.e., crawling up of a part of the insulating paste 15 leaked to the outside of the chip in to the upper surface (main surface) of the chip in upon pressing the chip in to the insulating film after applying the insulating paste on the die pad 3P3 using a multipoint nozzle or the like occurs. To a peripheral portion of the main surface of the chip 1D, the plurality of electrode pads 16 are formed, and thus surfaces of the electrode pads 16 are covered with the insulating paste 15 when the insulating paste 15 crawls to the main surface of the chip 1D. As a result, when one end of the Au wire 8 is bonded to the surface of the electrode pad 16, the electrode pad 16 and the Au wire 8 may not be contacted and/or adhesion of them may be largely degraded.

Accordingly, when the thickness of the chip 1D is 100 μm or smaller, the insulating paste 15 is applied onto the die pad 3P3 by the stamping method using the stamping nozzle 42 described above, the problem of crawling up of the insulating paste 15 to the upper surface of the chip 1D can be improved.

Also, as illustrated in FIG. 54, a top end of a fillet of the insulating paste 15 formed around the chip 1D is, in the same manner as the Ag paste 7, positioned between the main surface (upper surface) and the back surface (lower surface) of the chip 1D. it means, in other words, that it is important to set the volume of the dug portion 50 of the stamping nozzle 42 (i.e., the volume of the insulating paste 15 applied on the die pad 3P3) so that the position of the top end of the fillet of the insulating paste 15 is at the above-described position.

Note that, while an example of joining the chip 1D to which a driver IC is formed to the upper surface of the die pad 3P3 via the insulating paste 15 has been described, the Ag paste 7 may be used instead of the insulating paste 15. Since no electrode is formed to the back surface of the chip in to which a driver IC is formed, an electric problem will not be caused to occur even when the Ag paste 7 that is a conductive material is used.

By communalize the die-bonding material of the chips 1H and 1L and the die-bonding material of the chip 1D to the Ag paste 7, a baking furnace and baking conditions are standardized and the thermal curing process can be done at one time. It simplifies the number of assembling steps than performing thermal curing processes in two times using the insulating paste 15 as the die-bonding material of the chip 1D.

### Third Embodiment

While the semiconductor device mounting a chip in a chip mounting portion (die pad) of a lead frame has been described in the first and second embodiments, the present invention is applicable to a semiconductor device mounting a chip in a chip mounting portion of a wiring board.

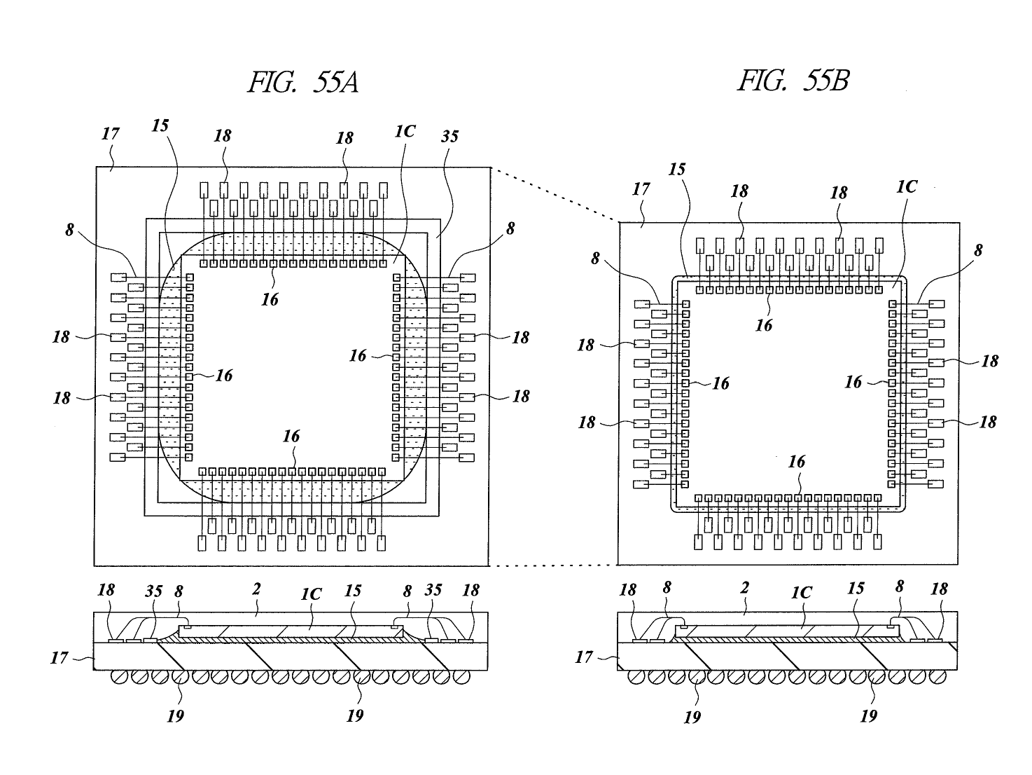

FIGS. 55A and 55B illustrate a BGA type semiconductor device mounting a chip 1M to which a multi-pin integrated circuit such as a microcomputer on a wiring board 17.

To an upper surface of the wiring board 17 to be a relay board (interposer) for connecting the chip 1M to a mother board of electronic parts, the chip 1C is mounted via the insulating paste 15 described above. In a peripheral portion of a main surface of the chip 1C, the plurality of electrode pads (bonding pads) 16 are formed, and, in a peripheral portion of an upper surface of the wiring board 17, a plurality of bonding leads 18 are formed. In addition, the electrode pads 16 of the chip 1C and the bonding leads 18 of the wiring board 17 are electrically connected. To a lower surface of the wiring board, a plurality of solder balls 19, which are electrically connected to the bonding leads 18 via wirings inside the wiring board 17 and via holes, are connected. The BGA is electrically connected to the mother board via the solder balls 19.

In such a manufacturing process of a BGA as described above in which the electrodes pads of the chip 1C and the bonding leads 18 of the wiring board 17 by the Au wires 8, when load is applied as the chip 1C is pressed from above onto the insulating paste 15 after applying the insulating paste 15 to the chip mounting portion of the upper surface of the wiring board 17, the insulating paste 15 leaked to the outside of the insulating paste 15 is wet and spread to the outside of the chip mounting portion and may attach to surfaces of the bonding leads 18, and as a result, the Au wire 8 may not be able to be connected to the bonding leads 18.

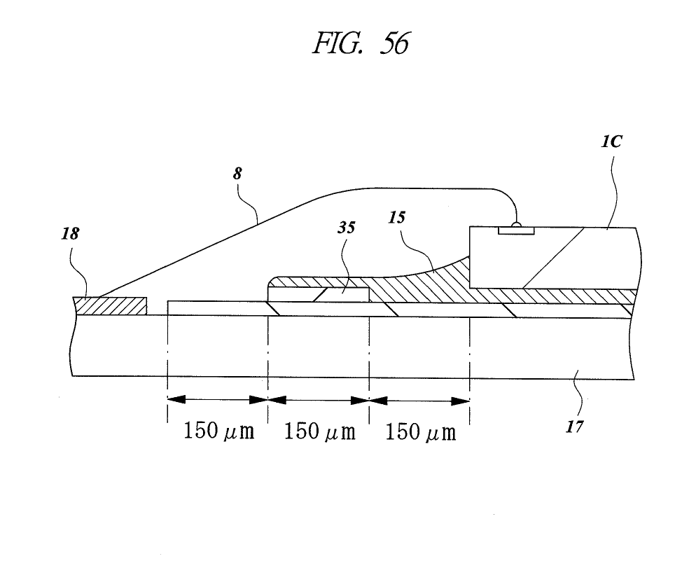

To avoid such wet spreading of the insulating paste 15, for example, a countermeasure is necessary such as widening the spacing from the chip mounting portion of the wiring board 17 to the bonding leads 18 and, as illustrated in FIG. 55A, surrounding the periphery of the chip mounting portion by a dam 35. However, when such a countermeasure is provided, the planar dimensions of the wiring board 17 are increased and downsizing of the BGA is disturbed. As illustrated in FIG. 56, when the periphery of the chip mounting portion is surrounded by the dam 35, when a width of the dam 35 is, e.g., 150 μm, spaces having a same level of widths of the dam 35 are required to the inside and the outside of the dam 35, respectively; thus, spaces of 450 μm in total are required.

Accordingly, by applying the insulating paste 15 to the chip mounting portion of the wiring board 17 by the stamping method using the stamping nozzle 42 described above, excessive wet spreading of the insulating paste 15 can be suppressed. In this manner, as compared to the existing method of applying the insulating paste 15 using a multi-point nozzle, the space from the chip mounting portion to the bonding leads 18 can be reduced and thus the planar dimensions of the BGA can be reduced as illustrated in FIG. 55B.

Note that, the effects described above do not depend on the thickness of the chip 1C mounted on the wiring board 17. That is, even when the thickness of the chip 1C exceeds 100 μm, the same effects can be achieved. Also, when the thickness of the chip 1C is 100 μm or smaller, the crawling up of the insulating paste 15 to the upper surface of the chip 1C can be suppressed too and thus thinning of the BGA can be advanced as compared to the existing method of applying the insulating paste 15 using a multi-point nozzle.

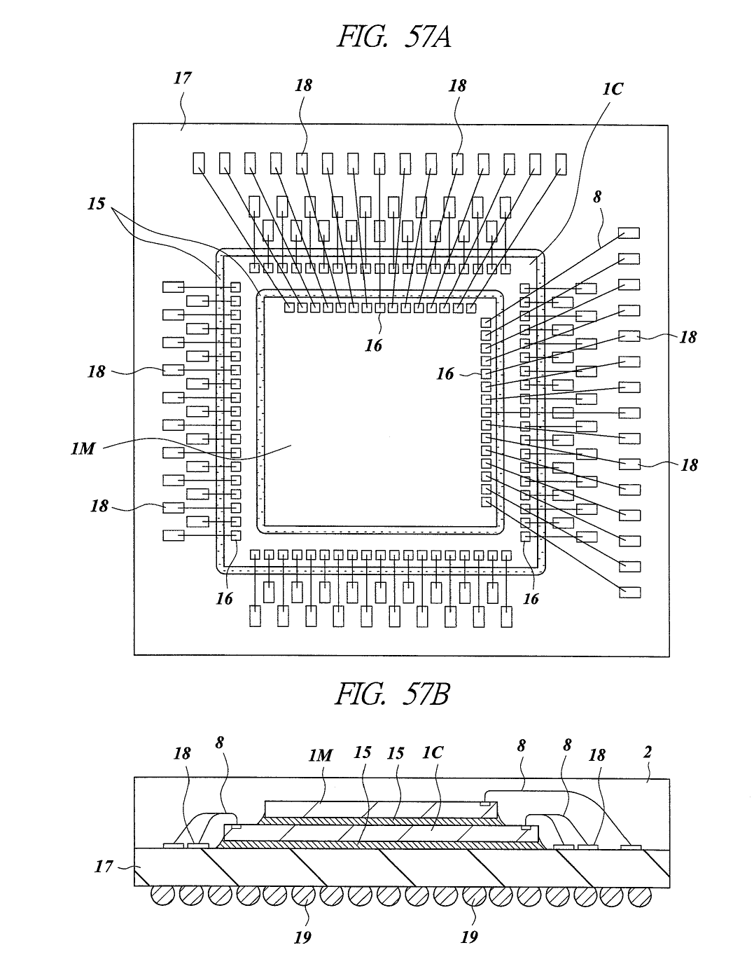

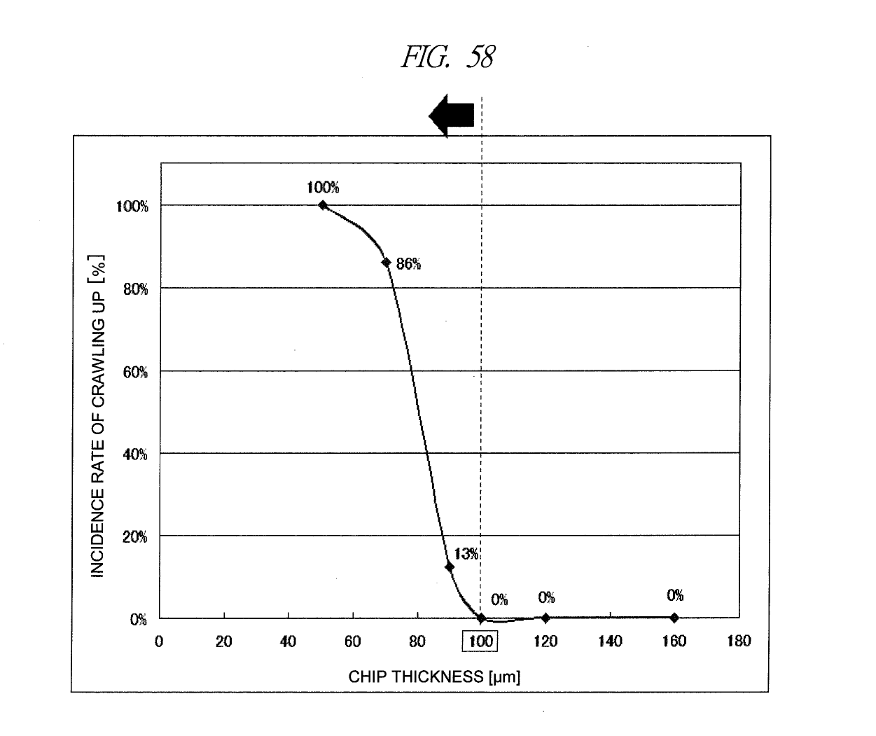

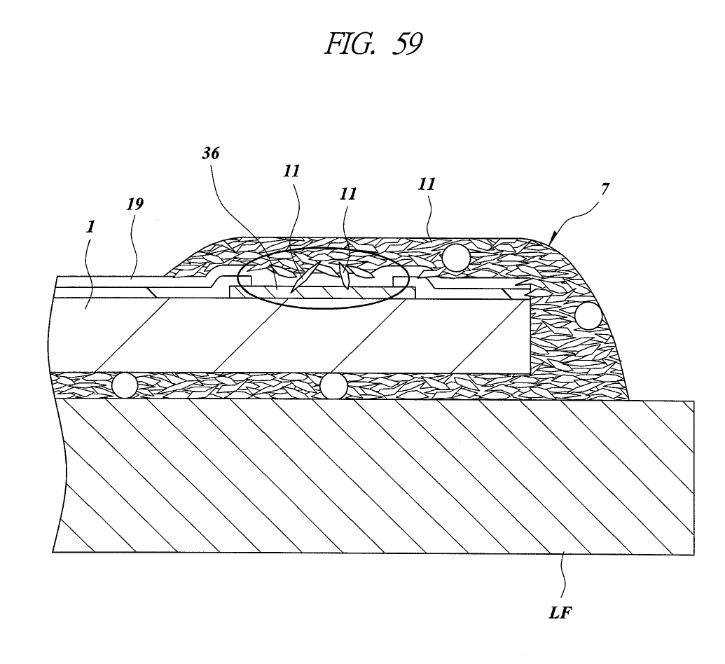

FIGS. 57A and 57B illustrate a stacked package in which a second chip 1M to which a memory circuit etc. are formed is stacked to an upper portion of the chip 1C mounted on the wiring board 17; FIG. 57A is a planar view and FIG. 57B is a cross-sectional view.

In the manufacturing process of such a stacked package, when the chip 1M is stacked on the chip 1C after applying the insulating paste 15 on the upper surface of the chip 1C using a multi-point nozzle, the insulating paste 15 wet and spread may attach to the bonding leads 18 of the chip 1C. Accordingly, in an existing way, an adhesive tape called DAF (Die Attach Film) has been used as the die-bonding material for stacking a chip on another chip. It is an adhesive tape for previously attaching to a back surface of a wafer upon dicing the wafer. Then, when the wafer to which the DAF is attached is diced, the DAF having the same external dimensions as a chip remains on a back surface of the singulated chip. Then, by stacking the chip 1M to which the DAF is adhered to is back surface on the chip 1C, the chip 1M can be adhered to the chip 1C without posing the problem of excessive wet spread of the insulating paste 15 as described above.

However, there is a problem of a high material cost in the DAF as compared with liquid die-bonding materials such as the insulating paste 15. Also, there are problems such that an apparatus for attaching the DAF to the back surface of the wafer is necessary and/or it is difficult to attach the DAF to the back surface of already singulated chips.

Accordingly, upon stacking the chip 1M on the chip 1C, when the insulating paste 15 is applied to the upper surface of the chip 1C using the stamping nozzle 42 described above, the excessive wet spread of the insulating paste 15 is suppressed and thus the stacked package can be manufactured at a low cost by using the insulating paste 15 that is cheaper than the DAF.

Note that, the effects described above are not limited to the case of using the chip 1M having a thickness of 100 μm or smaller, and the same effects can be achieved even when a chip having a thickness larger than 100 μm. Also, when the thickness of the chip 1M is 100 μm or smaller, the crawling up of the insulating paste 15 to the upper surface of the chip 1M can be suppressed too, and thus thinning of the stacked package can be advanced than the existing method of applying the insulating paste 15 using a multi-point nozzle.

Note that, while the case of stacking the chip 1M on the chip 1C has been described, it is also applicable to a case of additionally stacking another chip onto the chip 1M.

In the foregoing, the invention made by the inventors of the present invention has been concretely described based on the embodiments. However, it is needless to say that the present invention is not limited to the foregoing embodiments and various modifications and alterations can be made within the scope of the present invention.

Note that, the wiring board is not limited to a rigid board such as the wiring board 17 used for the lead frame LF or EGA described above. A flexible board and a rigid flexible board are included.

In addition, also with regard to the die-bonding material, it is not limited to the Ag paste 7, the solder paste 14 and the insulating paste 15, and the main features described above can be applied to other liquid paste materials having similar characteristics.

### INDUSTRIAL APPLICABILITY

The present invention is applicable to a semiconductor device and a method of manufacturing the semiconductor device in which a semiconductor chip is mounted on a wiring board using a paste die-bonding material.

1. A method of manufacturing a semiconductor device comprising the steps of :
(a) preparing a wiring board having a chip mounting portion and a plurality of lead terminals arranged to be adjacent to the chip mounting portion, and a semiconductor chip having a main surface to which a plurality of electrode pads and wirings are formed;
(b) applying a die-bonding material onto an upper surface of the chip mounting portion of the wiring board;
(c) mounting the semiconductor chip onto the upper surface of the chip mounting portion via the die-bonding material so that the upper surface of the chip mounting portion and the main surface of the semiconductor chip face a same direction;
(d) electrically connecting the plurality of electrode pads of the semiconductor chip and the plurality of lead terminals of the wiring board by a conductive material, respectively; and
(e) forming a sealing body for sealing the semiconductor chip and the conductive material,
the semiconductor chip having a thickness less than half of a thickness of the chip mounting portion,
the step (b) including filling the die-bonding material in a dug portion of a nozzle having the dug portion and transferring the die-bonding material onto the upper surface of the chip mounting portion of the wiring board so that an applied thickness of the die-bonding material is smaller than the thickness of the semiconductor chip.

2. The method of manufacturing a semiconductor device according to claim 1,
wherein the dug portion of the nozzle has a dug surface positioned above a lower surface of the nozzle;
a first opening is formed to the dug surface; and,
in the step (b), the die-bonding material is filled in the dug portion by discharging the die-bonding material from the first opening and presses the nozzle onto the chip mounting portion.

3. The method of manufacturing a semiconductor device according to claim 2,
wherein the discharge of the die-bonding material from the first opening is performed so that a lower end of the die-bonding material is positioned below the lower surface of the nozzle.

4. The method of manufacturing a semiconductor device according to claim 1,
wherein an applied shape of the die-bonding material transferred on the chip mounting portion is rectangular; and
external dimensions of the die-bonding material transferred on the chip mounting portion are smaller than external dimensions of the semiconductor chip.

5. The method of manufacturing a semiconductor device according to claim 4,
wherein, in the step (c), a whole surface of a back surface of the semiconductor chip is wetted by the die-bonding material.

6. The method of manufacturing a semiconductor device according to claim 4,
wherein, in the step (c), the die-bonding material is leaked from a periphery of the semiconductor chip.

7. The method of manufacturing a semiconductor device according to claim 1,
wherein a dug thickness of the dug portion of the nozzle is smaller than the thickness of the semiconductor chip.

8. The method of manufacturing a semiconductor device according to claim 1,
wherein the dug portion of the nozzle has a dug surface positioned above a lower surface of the nozzle,
a plurality of openings are formed to the dug surface, and
a first opening of the plurality of openings is arranged to be surrounded by the other openings.

9. The method of manufacturing a semiconductor device according to claim 8,
wherein a planar shape of the dug portion is rectangular, and
second, third, fourth, and fifth openings surrounding the first opening are arranged in a vicinity of corner portions of the dug surface.

10. The method of manufacturing a semiconductor device according to claim 1,
wherein the dug portion of the nozzle has a dug surface positioned above a lower surface of the nozzle,
a plurality of sidewalls surrounding the dug surface are formed between the lower surface of the nozzle and the dug surface, and
the dug surface and a surface of each of the plurality of sidewalls closer to the dug surface are subjected to mirror finish.

11. The method of manufacturing a semiconductor device according to claim 1,
wherein the dug portion of the nozzle has a dug surface positioned above a lower surface of the nozzle,
a plurality of sidewalls surrounding the dug surface are formed between the lower surface of the nozzle and the dug surface, and
a region in which the dug surface and the plurality of side surfaces respectively cross is in an “R” shape.

12. The method of manufacturing a semiconductor device according to claim 1,
wherein, the step (c) is performed using a bonding collet having external dimensions larger than external dimensions of the semiconductor chip.

13. The method of manufacturing a semiconductor device according to claim 1,
wherein the wiring board is a lead frame.

14. The method of manufacturing a semiconductor device according to claim 13,
wherein a power MOSFET is formed to the semiconductor chip.

15. The method of manufacturing a semiconductor device according to claim 14,
wherein the plurality of electrode pads of the semiconductor chip include a source electrode pad electrically connected to a source of the power MOSFET, and a gate electrode pad electrically connected to a gate electrode of the power MOSFET.

16. The method of manufacturing a semiconductor device according to claim 14,
wherein a drain electrode electrically connected to a drain of the power MOSFET is formed to a back surface of the semiconductor chip, and
the die-bonding material is an Ag paste or a solder paste.

17. The method of manufacturing a semiconductor device according to claim 15,
wherein, in the step (d), the source electrode pad and a source lead terminal of the plurality of lead terminals are electrically connected by an Al ribbon.

18. The method of manufacturing a semiconductor device according to claim 1,
wherein the die-bonding material is an Ag paste containing a spacer bead, and
a dug thickness of the dug portion formed to the nozzle is larger than a diameter of the spacer bead.

19. The method of manufacturing a semiconductor device according to claim 18,
wherein, in the step (c), the spacer bead is sandwiched between a back surface of the semiconductor chip and the upper surface of the chip mounting portion.

20. A method of manufacturing a semiconductor device comprising the steps of :
(a) preparing a wiring board having a chip mounting portion and a plurality of lead terminals arranged to be adjacent to the chip mounting portion, and a semiconductor chip having a main surface to which a plurality of electrode pads and wirings are formed;
(b) applying a die-bonding material onto an upper surface of the chip mounting portion of the wiring board;
(c) mounting the semiconductor chip onto the chip mounting portion via the die-bonding material so that the upper surface of the chip mounting portion and the main surface of the semiconductor chip face the same direction;
(d) electrically connecting the plurality of electrode pads and the plurality of lead terminals of the wiring board by a conductive material, respectively; and
(e) forming a sealing body sealing the semiconductor chip and the conductive material,
the semiconductor chip having a thickness smaller than 100 μm and,
the step (b) including filling the die-bonding material in a dug portion of a nozzle having the dug portion and transferring the die-bonding material filled in the dug portion onto the chip mounting portion of the wiring board so that an applied thickness of the die-bonding material is thinner than a thickness of the semiconductor chip.

21. The method of manufacturing a semiconductor device comprising the steps of:
(a) preparing a lead frame having a chip mounting portion and a plurality of lead framed arranged to be adjacent to the chip mounting portion, and a semiconductor chip including a power MOSFET having a main surface to which a source electrode pad, a gate electrode pad, and a wiring and having a back surface to which a drain electrode is formed;
(b) applying an Ag paste onto an upper surface of the chip mounting portion of the lead frame;
(c) mounting the semiconductor chip onto the upper surface of the chip mounting portion so that the upper surface of the chip mounting portion and the main surface of the semiconductor chip face a same direction and electrically connecting the drain electrode of the semiconductor chip and the chip mounting portion of the lead frame;
(d) electrically connecting the source electrode pad of the semiconductor chip and a source lead terminal of the plurality of lead terminals of the lead frame by a conductive material and electrically connecting the gate electrode pad of the semiconductor chip and a gate lead terminal of the plurality of lead terminals of the lead frame by a conductive material; and
(e) forming a sealing body sealing the semiconductor chip and the conductive material,
the semiconductor chip having a thickness less than half of a thickness of the chip mounting portion,
the step (b) including filling of the Ag paste in a dug portion of a nozzle having the dug portion and transferring of the Ag paste onto the upper surface of the chip mounting portion of the lead frame so that an applied thickness is smaller than the thickness of the semiconductor chip.

22. A semiconductor device comprising:
a semiconductor chip having a main surface to which a plurality of electrode pads and wirings are formed;
a chip mounting portion having an upper surface to which the semiconductor chip is mounted via a die-bonding material;
a plurality of lead terminals arranged adjacently to the semiconductor chip;
a conductive material electrically connecting the plurality of electrode pads of the semiconductor chip and the plurality of lead terminals; and
a sealing body sealing the semiconductor chip and the conductive material,
the semiconductor chip having a thickness less than half of a thickness of the chip mounting portion, and
the semiconductor chip having a whole of a back surface being wetted by the die-bonding material.

23. The semiconductor device according to claim 22,
wherein the die-bonding material leaks to the outside of a periphery of the semiconductor chip;
when taking a distance from a first corner portion of the semiconductor chip to an outer circumference of the die-bonding material leaked from the first corner portion in a 45° direction is “a” and taking a distance from the first corner portion to an outer circumference of the die-bonding material leaked in a direction perpendicular to a first side of the semiconductor chip is “b”, b/a<2.

24. The semiconductor chip according to claim 22,
wherein the die-bonding material is an Ag paste containing a spacer bead, and
the spacer bead is sandwiched between the back surface of the semiconductor chip and the upper surface of the chip mounting portion.

25. The semiconductor device according to claim 22,
wherein a power MOSFET is formed to the semiconductor chip,
the plurality of electrode pads include a source electrode pad electrically connected to a source of the power MOSFET,
the plurality of lead terminals include a source lead terminal, and
the source electrode pad and the source lead terminal are electrically connected by an Al ribbon.

26. A semiconductor device comprising:
a semiconductor chip having a main surface to which a plurality of electrode pads and a wiring are formed;
a chip mounting portion having an upper surface to which the semiconductor chip is mounted via a die-bonding material;
a plurality of lead terminals arranged adjacently to the chip mounting portion;
a conductive material electrically connecting the plurality of electrode pads of the semiconductor chip and the plurality of lead terminals; and
a sealing body sealing the semiconductor chip and the conductive material,
the semiconductor chip having a thickness smaller than 100 μm,
the semiconductor chip having the whole of its back surface being wetted by the die-bonding material.
